(19) United States
(12) Patent Application Publication
(10) Pub. No.: US 2024/0196664 A1
(43) Pub. Date: Jun. 13, 2024

(54) LIGHT EMITTING DISPLAY DEVICE

(71) Applicant: Samsung Display Co., LTD., Yongin-si (KR)

(72) Inventors: Hye Won KIM, Yongin-si (KR); Chung Sock CHOI, Yongin-si (KR); Yoo Min KO, Yongin-si (KR); Sun Ho KIM, Yongin-si (KR); Ju Chan PARK, Yongin-si (KR); Pil Suk LEE, Yongin-si (KR); Sung Jin HONG, Yongin-si (KR)

(73) Assignee: Samsung Display Co., LTD., Yongin-si (KR)

(21) Appl. No.: 18/524,009

(22) Filed: Nov. 30, 2023

(30) Foreign Application Priority Data
Dec. 7, 2022 (KR) 10-2022-0169696

(51) Int. Cl. H10K 59/123; H10K 59/121; H10K 59/122

(52) U.S. Cl. CPC H10K 59/123; H10K 59/1213; H10K 59/1216; H10K 59/122

(57) ABSTRACT

A light emitting display device includes a first display area, and a second display area disposed outside of the first display area. The second display area includes a pixel driver, a main light-emitting device electrically connected to the pixel driver, and an additional light-emitting device electrically connected to the main light-emitting device. The additional light-emitting device overlaps a peripheral driver that generates signals that are provided to the pixel driver. The main light-emitting device and the additional light-emitting device include a first electrode, an emission layer, and a second electrode. The pixel driver is electrically connected to the second electrode of the main light-emitting device and the second electrode of the additional light-emitting device. The second electrode of the additional light-emitting device and the second electrode of the main light-emitting device are surrounded by a separator in a plan view.

### CROSS-REFERENCE TO RELATED APPLICATION(S)

This application claims priority to and benefits of Korean Patent Application No. 10-2022-0169696 under 35 U.S.C. § 119, filed in the Korean Intellectual Property Office on Dec. 7, 2022, the entire contents of which are incorporated herein by reference.

### BACKGROUND

### 1. Technical Field

The disclosure relates to disposing a light-emitting device in a non-display area to display images.

### 2. Description of the Related Art

A display device may include a display area for displaying images and a non-display area displaying no images. Pixels may be disposed in a row direction and a column direction in the display area. Various elements such as transistors or capacitors and various wires for supplying signals to them may be disposed in the respective pixels. Various peripheral drivers (a scan signal generator, a data driver, a timing controller, etc.) and wires for transmitting electrical signals for driving the pixels may be disposed in the non-display area.

Regarding some display devices, a camera or a sensor may be disposed in the display area, and there may be a portion displaying no images in a predetermined or selected region of the display area. Such display devices have an advantage of reducing the non-display area, but have the drawback that the non-display area displaying no images is disposed in the display area.

The above information disclosed in this Background section is only for enhancement of understanding of the background of the disclosure, and therefore it may contain information that does not form the prior art that is already known in this country to a person of ordinary skill in the art.

### SUMMARY

The disclosure has been made in an effort to provide a light emitting display device for increasing a display area or reducing an area occupied by a non-display area.

The disclosure has been made in an effort to provide a light emitting display device for changing a non-display area into a display area by use of a separator.

An embodiment of the disclosure provides a light emitting display device that may include a first display area, and a second display area disposed outside of the first display area. The second display area may include a pixel driver, a main light-emitting device electrically connected to the pixel driver, and an additional light-emitting device electrically connected to the main light-emitting device. The additional light-emitting device may overlap a peripheral driver that generates signals that are provided to the pixel driver. The main light-emitting device and the additional light-emitting device may include a first electrode, an emission layer, and a second electrode. The pixel driver may be electrically connected to the second electrode of the main light-emitting device and the second electrode of the additional light-emitting device. The second electrode of the additional light-emitting device and the second electrode of the main light-emitting device may be surrounded by a separator in a plan view.

The second electrode of the additional light-emitting device and the second electrode of the main light-emitting device electrically connected to each other may be integral with each other.

The second electrode may include a first portion overlapping the emission layer of the main light-emitting device in a plan view, a second portion overlapping the emission layer of the additional light-emitting device in a plan view, and a connector that connects the first portion and the second portion.

A width of the connector may be narrower than a width of the first portion and a width of the second portion.

A first electrode of the main light-emitting device and a first electrode of the additional light-emitting device may be electrically connected to a first driving voltage line.

The light emitting display device may further include a cathode connecting line that electrically connects the second electrode of the main light-emitting device and the pixel driver.

The cathode connecting line may have a triple-layered structure, and the second electrode of the main light-emitting device may side-contact the cathode connecting line.

The light emitting display device may further include an auxiliary connecting electrode disposed between the second electrode of the main light-emitting device and the cathode connecting line side-contacting each other, wherein the auxiliary connecting electrode, the first electrode of the main light-emitting device, and the first electrode of the additional light-emitting device may be made of a same material.

Three contact holes that connect the cathode connecting line and the auxiliary connecting electrode may be adjacently disposed in a direction.

The separator may be disposed among the three contact holes in a plan view, and the separator may be bent around the three contact holes.

Another embodiment of the disclosure provides a light emitting display device that may include a first display area, and a component area surrounded by the first display area and disposed on a front side of a camera disposed on a rear side of the component area. The component area may include a pixel driver, and a main light-emitting device and an additional light-emitting device that are electrically connected to the pixel driver. The component area may further include a light transmitting area that transmits light to the camera. The main light-emitting device and the additional light-emitting device may include a first electrode, an emission layer, and a second electrode. The pixel driver may be electrically connected to the second electrode of the main light-emitting device and the second electrode of the additional light-emitting device. The second electrode of the additional light-emitting device and the second electrode of the main light-emitting device may be surrounded by a separator in a plan view.

The second electrode of the additional light-emitting device and the second electrode of the main light-emitting device electrically connected to each other may be integral with each other.

The second electrode may include a first portion overlapping the emission layer of the main light-emitting device in a plan view, a second portion overlapping the emission layer of the additional light-emitting device in a plan view, and a connector that connects the first portion and the second portion.

A width of the connector may be narrower than a width of the first portion and a width of the second portion.

A first electrode of the main light-emitting device and a first electrode of the additional light-emitting device may be electrically connected to a first driving voltage line.

The light emitting display device may further include a cathode connecting line that electrically connects the second electrode of the main light-emitting device and the pixel driver.

The cathode connecting line may include a triple-layered structure, and the second electrode of the main light-emitting device may side-contact the cathode connecting line.

The light emitting display device may further include an auxiliary connecting electrode disposed between the second electrode of the main light-emitting device and the cathode connecting line side-contacting each other, wherein the auxiliary connecting electrode, the first electrode of the main light-emitting device, and the first electrode of the additional light-emitting device may be made of a same material.

Three contact holes that connect the cathode connecting line and the auxiliary connecting electrode may be adjacently disposed in a direction.

The separator may be disposed among the three contact holes in a plan view, and the separator may be bent around the three contact holes.

According to the embodiments, the light-emitting device may be disposed on the upper portion of the region in which the camera is disposed on the upper portion or the rear side of the peripheral driver so the display area may be increased or the area occupied by the non-display area may be reduced.

According to the embodiments, the cathode of the light-emitting device disposed on the upper portion of the region in which the camera is disposed and the cathode of the light-emitting device disposed on the upper portion of the pixel driver may be partitioned by using the separator and may be connected to each other on the upper portion or the rear side of the peripheral driver, thereby forming the two light-emitting devices that are readily connected to each other.

### BRIEF DESCRIPTION OF THE DRAWINGS

FIG. 1 is a schematic top plan view of a light emitting display device according to an embodiment.

FIG. 2 is a schematic cross-sectional view of a portion of FIG. 1.

FIG. 3 is a schematic diagram of an equivalent circuit of a pixel included in a light emitting display device according to an embodiment.

FIG. 4 is a schematic waveform diagram of signals applied to a pixel of FIG. 3.

FIG. 5 is a schematic diagram of an equivalent circuit of a pixel included in a light emitting display device according to another embodiment.

FIG. 6 is a schematic top plan view of a connection between a pixel driver and a light-emitting device according to an embodiment.

FIG. 7 is a schematic cross-sectional view of a connection of a light-emitting device according to an embodiment of FIG. 6.

FIG. 8 is a schematic top plan view of a light emitting display device according to another embodiment.

FIG. 9 is a schematic top plan view of a connection between a pixel driver and a light-emitting device according to an embodiment.

FIG. 10 is a schematic cross-sectional view of a connection of a light-emitting device according to an embodiment of FIG. 9.

FIG. 11 is a schematic top plan view of a light emitting display device according to another embodiment.

FIG. 12 is a schematic cross-sectional view of a portion of FIG. 11.

FIG. 13 is a schematic top plan view of a connection between a pixel driver and a light-emitting device according to an embodiment.

FIG. 14 is a schematic cross-sectional view of a connection of a light-emitting device according to an embodiment of FIG. 13.

### DETAILED DESCRIPTION OF THE EMBODIMENTS

The disclosure will be described more fully hereinafter with reference to the accompanying drawings, in which embodiments are shown. As those skilled in the art would realize, the described embodiments may be modified in various different ways, all without departing from the spirit or scope of the disclosure.

The drawings and description are to be regarded as illustrative in nature and not restrictive, and like reference numerals designate like elements throughout the specification.

The size and thickness of each configuration shown in the drawings may be arbitrarily shown for better understanding and ease of description, but the disclosure is not limited thereto.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that when an element such as a layer, film, region, or substrate is referred to as being “on” another element, it can be directly on the other element or intervening elements may also be present. In contrast, when an element is referred to as being “directly on” another element, there may be no intervening elements present. The word “on” or “above” means positioned on or below the object portion, and does not necessarily mean positioned “on” or “above” the upper side of the object portion based on a gravitational direction.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in plan view” means viewing the object portion from the top, and the phrase “on a cross-section” means viewing a cross-section of which the object portion is vertically cut from the side.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween. Further, two parts may be integral with each other and be “connected.”

It will be understood that the terms “connected to” or “coupled to” may include a physical and/or electrical connection or coupling.

When the parts such as wires, layers, films, regions, plates, or constituent elements are described to extend in the “first direction” or the “second direction”, this not only signifies a straight-line shape running straight in a corresponding direction, but also includes a structure generally extending in the first direction or the second direction, a structure bent on a predetermined or selected portion, a zigzag-shaped structure, or a structure including a curved structure and extending in a direction.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Electronic devices (e.g., mobile phones, TVs, monitors, laptop computers, etc.,) including the display device and the display panel described in the specification or the electronic devices including the display device and the display panel manufactured by a manufacturing method described in the specification, are not excluded from the scope of this disclosure.

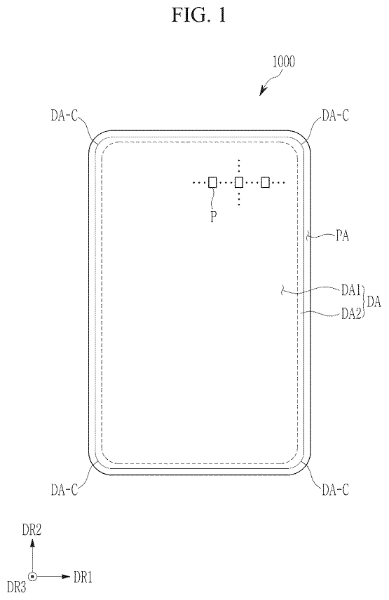

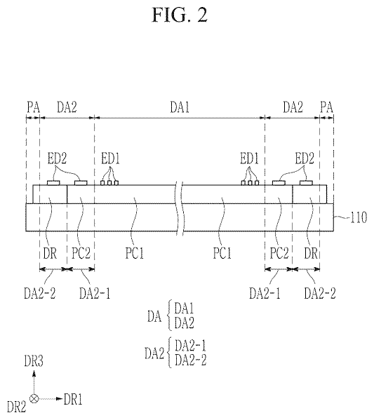

A schematic structure of a light emitting display device according to an embodiment will now be described with reference to FIG. 1 and FIG. 2.

FIG. 1 is a schematic top plan view of a light emitting display device according to an embodiment, and FIG. 2 is a schematic cross-sectional view of a portion of FIG. 1.

Referring to FIG. 1, the light emitting display device 1000 may include a display area DA in which pixels P may be disposed and which displays images, and a non-display area PA disposed near the display area DA. The non-display area PA may not display images.

The display area DA may have a quadrangular shape, and depending on embodiments, as shown in FIG. 1, respective corners DA-C of the display area DA may have a round shape. The non-display area PA may surround the display area DA. However, without being limited thereto, the display area DA and the non-display area PA may have various shapes.

The display area DA may include a first display area DA1, and a second display area DA2 disposed between the first display area DA and the non-display area PA.

The first display area DA1 may be disposed in a center of the display area DA, and the second display area DA2 may be disposed on respective sides of the first display area DA1, for example, a right and a left. Referring to FIG. 1, the second display area DA2 may be disposed on the respective sides of the first display area DA1 in a first direction DR1 and also on respective sides, for example, an upper side and a lower side, of a second direction DR2. However, this is an example, and positions of the first display area DA1 and the second display area DA2 may be changeable in many ways. For example, the first display area DA1 may substantially have a quadrangular shape, and the second display area DA2 may be disposed on at least two sides and corners of the first display area DA1.

The non-display area PA may surround the display area DA. The non-display area PA may not display images, and may be disposed on an outside of the light emitting display device 1000. At least part of the light emitting display device 1000 may be a flexible display device including a bending portion. For example, the center of the light emitting display device 1000 may be flat, and edges thereof may be bent. In this instance, at least part of the second display area DA2 may be disposed on the bending portion so at least part of the second display area DA2 may be bent.

A side of the light emitting display device 1000, for displaying images, may be parallel to a side defined by the first direction DR1 and the second direction DR2. A normal direction of the side for displaying images, for example, a thickness direction of the light emitting display device 1000 is indicated by a third direction DR3. Front sides (or upper sides) and rear sides (or lower sides) of respective members may be distinguished by the third direction DR3. However, directions indicated by the first to third directions DR1, DR2, and DR3 are relative concepts and they may be changed to other directions.

The light emitting display device 1000 may further include a touch unit and/or a cover window on the upper side.

The light emitting display device 1000 may be a flat rigid display device, or may be a flexible display device without being limited thereto. The light emitting display device may include an organic or inorganic emission layer, and may include a color converting layer and/or a color filter including quantum dots.

Referring to FIG. 2, a cross-sectional structure of the first display area DA1, the second display area DA2, and the non-display area PA of the light emitting display device 1000 is shown.

The light emitting display device 1000 may include a substrate 110, pixel drivers PC1 and PC2 disposed on the substrate 110, and light-emitting devices ED1 and ED2 for receiving light emitting currents from the pixel drivers PC1 and PC2.

The light-emitting devices ED1 and ED2 may emit predetermined light to display luminance or may add the light to the luminance to display colors. Here, the displayable colors may be red, green, blue, and white light. The light emitting display device 1000 may display images through the light emitted by the light-emitting devices ED1 and ED2.

The light-emitting devices ED1 and ED2 may include a first light-emitting device ED1 and a second light-emitting device ED2. The light-emitting devices ED1 and ED2 may be disposed in the display area DA.

The first light-emitting device ED1 may be disposed in the first display area DA1, and the second light-emitting device ED2 may be disposed in the second display area DA2.

Referring to FIG. 2, part of the second light-emitting device ED2 may be disposed on the upper portion of the peripheral driver DR. The light emitting display device 1000 may include first light-emitting devices ED1 and second light-emitting devices ED2. The first light-emitting devices ED1 may be disposed in the first direction DR1 and the second direction DR2 in the first display area DA1, and the second light-emitting devices ED2 may be disposed in the first direction DR1 and the second direction DR2 in the second display area DA2. The size of the first light-emitting device ED1 may be equal to/different from the size of the second light-emitting device ED2. For example, the second light-emitting device ED2 may be bigger than the first light-emitting device ED1. The number of the first light-emitting devices ED1 per area may be equal to/different from the number of the second light-emitting devices ED2 per area. For example, the number of the second light-emitting devices ED2 per area may be less than the number of the first light-emitting device ED1 per area. A resolution of the first display area DA1 may be equal to/different from a resolution of the second display area DA2. For example, the resolution of the first display area DA1 may be higher than the resolution of the second display area DA2. Dispositions and sizes of the first light-emitting device ED1 and the second light-emitting device ED2 and the resolutions of the first display area DA1 and the second display area DA2 are not limited thereto and may be modifiable in many ways.

Regarding the light emitting display device 1000, the pixel drivers PC1 and PC2 disposed on the substrate 110 may include a first pixel driver PC1 and a second pixel driver PC2. Referring to FIG. 2, the first pixel driver PC1 represents a region in which multiple first pixel drivers PC1 may be substantially disposed in the first direction DR1 and the second direction DR2, and the second pixel driver PC2 represents a region in which multiple second pixel drivers PC2 may be substantially disposed in the first direction DR1 and the second direction DR2. The disposition of the pixel drivers PC1 and PC2 are not limited, and they may be arranged in many ways. The first pixel driver PC1 may be disposed in the first display area DA1, and the second pixel driver PC2 may be disposed in the second display area DA2. The pixel drivers PC1 and PC2 may be connected to at least one of the light-emitting devices ED1 and ED2. One first pixel driver PC1 may be connected to one first light-emitting device ED1, and one second pixel driver PC2 may be connected to at least two second light-emitting devices ED2. The size of one first pixel driver PC1 may be equal to/different from the size of one second pixel driver PC2. For example, the one second pixel driver PC2 may be bigger than the one first pixel driver PC1.

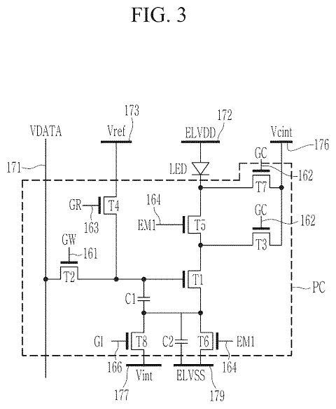

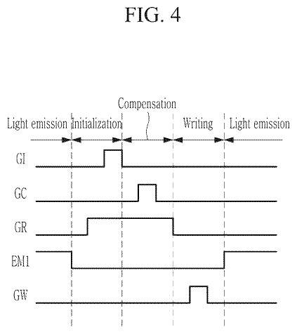

Referring to FIG. 2, the light emitting display device 1000 may further include a peripheral driver DR disposed on the substrate 110. The peripheral driver DR may generate signals for operating the first pixel driver PC1 and the second pixel driver PC2 and transmit the same, and may be electrically connected to the first pixel driver PC1 and the second pixel driver PC2. The peripheral driver DR may, for example, include signal generators such as a scan signal generator or a light emitting control signal generator and signal transmitting wires connected thereto. The peripheral driver DR may include a generator for generating a first scan signal GW, a second scan signal GC, a third scan signal GR, a fourth scan signal GI, and a first light emitting signal EM1 to be described with reference to FIG. 3 and FIG. 4. The peripheral driver DR may further include a data driver or wires (a driving voltage supply line, a common voltage supply line, etc.) for transmitting voltages. At least part of the peripheral driver DR may be disposed in the second display area DA2, and depending on embodiments, part of the peripheral driver DR may be disposed in the non-display area PA.

The first display area DA1 may emit light by the first light-emitting device ED1. The first light-emitting device ED1 for receiving light emitting currents from the first pixel driver PC1 and the first pixel driver PC1 may be formed in the first display area DA1. In this instance, at least part of the first light-emitting device ED1 may overlap the first pixel driver PC1 electrically connected to the first light-emitting device ED1. A combination of the first pixel driver PC1 formed in the first display area DA1 and the first light-emitting device ED1 for receiving the light emitting current from the same will be referred to as a first pixel or a normal pixel of the first display area. The first pixel driver PC1 and the first light-emitting device ED1 may be referred to as a normal pixel driver and a normal light-emitting device.

The second display area DA2 may emit light by the second light-emitting device ED2, and may be distinguished into a second-1 display area DA2-1 and a second-2 display area DA2-2. The second pixel driver PC2 may be disposed in the second-1 display area DA2-1, and the peripheral driver DR may be disposed in the second-2 display area DA2-2. The second light-emitting device ED2 for receiving the light emitting current from the second pixel driver PC2 may be disposed in the second-1 display area DA2-1 and the second-2 display area DA2-2. The second light-emitting device ED2 may be distinguished into a second light-emitting device ED2 disposed on an upper portion of the second pixel driver PC2 and a second light-emitting device ED2 disposed on an upper portion of the peripheral driver DR. The second light-emitting device ED2 disposed on the peripheral driver DR may configure the second-2 display area DA2-2, and receive the light emitting current from at least part of the second pixel driver PC2 disposed in the second-1 display area DA2-1. The second pixel driver PC2 may be distinguished into a second pixel driver PC2 for transmitting an output current to the second light-emitting device ED2 configuring the second-1 display area DA2-1 and a second pixel driver PC2 for transmitting an output current to the second light-emitting device ED2 configuring the second-2 display area DA2-2. One second pixel driver PC2 transmits an output current to the second light-emitting devices ED2, and at least one of the second light-emitting devices ED2 may be disposed in the second-2 display area DA2-2 and may be disposed on the peripheral driver DR.

Regarding the light emitting display device according to a comparative example, the pixel driver and the light-emitting device may be disposed in the display area, and the light-emitting device may not be disposed in the region in which the peripheral driver is disposed. Therefore, the non-display area in which the peripheral driver is disposed may not display images, and a dead space (e.g., area with no image) may be formed. In contrast, part of the second light-emitting device ED2 is disposed on a portion in which the peripheral driver DR is disposed so the light emitting display device may display images and the display area may be increased. For example, as second light-emitting device ED2 is disposed on the peripheral driver DR, the dead space may be reduced, and the region displaying no images may be reduced.

A circuit structure of the light-emitting devices ED1 and ED2 and the pixel drivers PC1 and PC2 (also referred to as PC) will now be described with reference to FIG. 3 to FIG. 5.

A pixel, and signals applied thereto, and an operation thereof according to an embodiment will now be described in detail with reference to FIG. 3 and FIG. 4.

FIG. 3 is a schematic diagram of an equivalent circuit diagram of a pixel included in a light emitting display device according to an embodiment.

Referring to FIG. 3, the pixel may include a light-emitting device LED and a pixel driver for driving the same. The pixel driver may include all the elements exclusive of the light-emitting device LED in FIG. 3, and the pixel driver of the pixel according to an embodiment of FIG. 3 may include a first transistor T1, a second transistor T2, a third transistor T3, a fourth transistor T4, a fifth transistor T5, a sixth transistor T6, a seventh transistor T7, an eighth transistor T8, a first capacitor C1, and a second capacitor C2.

The pixel driver may be connected to a first scan line 161 for applying the first scan signal GW, a second scan line 162 for applying the second scan signal GC, a third scan line 163 for applying the third scan signal GR, a fourth scan line 166 for applying the fourth scan signal GI, a first light emitting signal line 164 for applying the first light emitting signal EM1, and a data line 171 for applying the data voltage VDATA. The pixel may be connected to a first driving voltage line 172 for applying a driving voltage ELVDD (also referred to as a first driving voltage), a second driving voltage line 179 for applying a low driving voltage ELVSS (also referred to as a second driving voltage), a reference voltage line 173 for applying a reference voltage Vref, a first initialization voltage line 177 for applying a first initialization voltage Vint, and a second initialization voltage line 176 for applying a second initialization voltage Vcint.

A circuit structure of a pixel will now be described with a focus on respective elements including transistors, capacitors, and light-emitting devices included in the pixel.

The first transistor T1 (also referred to as a driving transistor) may include a gate electrode connected to a first electrode of the first capacitor C1, a second electrode of the second transistor T2, and a second electrode of the fourth transistor T4, a first electrode (an input-side electrode) connected to a second electrode of the third transistor T3 and a second electrode of the fifth transistor T5, and a second electrode (an output-side electrode) connected to a first electrode of the sixth transistor T6, a second electrode of the eighth transistor T8, a second electrode of the first capacitor C1, and a second electrode of the second capacitor C2.

A degree for the first transistor T1 to be turned on may be set according to a voltage at the gate electrode, and the size of the current flowing to the second electrode of the first transistor T1 from the first electrode may be set according to the turned-on degree. The current flowing to the second electrode of the first transistor T1 from the first electrode may be equivalent to the current flowing to the light-emitting device LED for a light emitting section so it may also be referred to as a light emitting current. Here, the first transistor T1 may be formed of an n-type transistor, and the light emitting current may flow as the voltage at the gate electrode increases. In case that the light emitting current increases, the light-emitting device LED may display high luminance.

The second transistor T2 (also referred to as a data input transistor) may include a gate electrode connected to the first scan line 161 for applying the first scan signal GW, a first electrode (an input-side electrode) connected to the data line 171 for applying the data voltage VDATA, and a second electrode (an output-side electrode) connected to a first electrode of the first capacitor C1, a gate electrode of the first transistor T1, and a second electrode of the fourth transistor T4. The second transistor T2 may input the data voltage VDATA into the pixel according to the first scan signal GW to transmit the same to the gate electrode of the first transistor T1, and may store the same in the first electrode of the first capacitor C1.

The third transistor T3 (also referred to as a first voltage transmitting transistor or second initialization voltage transmitting transistor) may include a gate electrode connected to the second scan line 162 for applying the second scan signal GC, a first electrode (an input-side electrode) connected to the second initialization voltage line 176 for applying the second initialization voltage Vcint, and a second electrode (an output-side electrode) connected to the first electrode of the first transistor T1 and the second electrode of the fifth transistor T5. The third transistor T3 may transmit the second initialization voltage Vcint to the first transistor T1 without passing through the light-emitting device LED. Here, the second initialization voltage Vcint may have a positive voltage value in a like way of the first driving voltage ELVDD. Depending on embodiments, not the second initialization voltage Vcint but the first driving voltage ELVDD or a bias voltage (Vbias) may be applied. In case that the current flows to the light-emitting device LED, the light-emitting device LED may unnecessarily emit light, so the third transistor T3 may transmit the second initialization voltage Vcint to the first transistor T1 on an individual path. Therefore, the third transistor T3 may not be turned on for a light emitting section, and it may be turned on for other sections.

The fourth transistor T4 (also referred to as a reference voltage transmitting transistor) may include a gate electrode connected to the third scan line 163 for applying the third scan signal GR, a first electrode connected to the reference voltage line 173, and a second electrode connected to the first electrode of the first capacitor C1, the gate electrode of the first transistor T1, and the second electrode of the second transistor T2. The fourth transistor T4 may transmit the reference voltage Vref to the first electrode of the first capacitor C1 and the gate electrode of the first transistor T1 and may initialize the same.

The fifth transistor T5 (also referred to as a cathode connecting transistor) may include a gate electrode connected to the first light emitting signal line 164 for applying the first light emitting signal EM1, a first electrode connected to the cathode of the light-emitting device LED and the second electrode of the seventh transistor T7, and a second electrode connected to the first electrode of the first transistor T1 and the second electrode of the third transistor T3. The fifth transistor T5 may connect the first electrode of the first transistor T1 and the light-emitting device LED based on the first light emitting signal EM1 to form a current path and allow the light-emitting device LED to emit light.

The sixth transistor T6 (also referred to as a low driving voltage applying transistor) may include a gate electrode connected to the first light emitting signal line 164 for applying the first light emitting signal EM1, a first electrode connected to the second electrode of the first transistor T1, the second electrode of the eighth transistor T8, the second electrode of the first capacitor C1, and the second electrode of the second capacitor C2, and a second electrode for receiving a second driving voltage ELVSS. The sixth transistor T6 may transmit the second driving voltage ELVSS to the second electrode of the first transistor T1 based on the first light emitting signal EM1 or may block the same.

The seventh transistor T7 (also referred to as a second voltage transmitting transistor) may include a gate electrode connected to the second scan line 162 for applying the second scan signal GC, a first electrode (an input-side electrode) connected to the second initialization voltage line 176, and a second electrode (an output-side electrode) connected to the cathode of the light-emitting device LED and the first electrode of the fifth transistor T5. The seventh transistor T7 may transmit the second initialization voltage Vcint to the cathode, and change a voltage level of the cathode to the second initialization voltage Vcint to remove the problem of failing to display black because of charges remaining at the cathode and resultantly accurately display black. Here, the second initialization voltage Vcint may have a positive voltage value in a similar way to the first driving voltage ELVDD. Depending on embodiments, not the second initialization voltage Vcint but the first driving voltage ELVDD or the bias voltage (Vbias) may be applied.

The eighth transistor T8 (also referred to as a first initialization voltage transmitting transistor) may include a gate electrode connected to the fourth scan line 166 for applying the fourth scan signal GI, a first electrode (an input-side electrode) connected to the first initialization voltage line 177, and a second electrode (an output-side electrode) connected to the second electrode of the first transistor T1, the first electrode of the sixth transistor T6, the second electrode of the first capacitor C1, and the second electrode of the second capacitor C2. The eighth transistor T8 may transmit the first initialization voltage Vint to the second electrode of the first transistor T1, the first electrode of the sixth transistor T6, the second electrode of the first capacitor C1, and the second electrode of the second capacitor C2 and initialize the same.

Regarding an embodiment of FIG. 3, all the transistors may be formed with n-type transistors, and the transistors may be turned on in case that the voltage at the gate electrode is a high-level voltage, and they may be turned off in case that the voltage is a low-level voltage. Semiconductor layers included in the respective transistors may use polycrystalline silicon semiconductors or oxide semiconductors, and may additionally use amorphous semiconductors or monocrystalline semiconductors.

Depending on embodiments, the semiconductor layers included in the respective transistors may further include overlapping layers (or additional gate electrodes), and may improve displaying quality of the pixel by applying voltages to the overlapping layers (or additional gate electrodes) and changing characteristics of the transistors.

The first capacitor C1 may include a first electrode connected to the gate electrode of the first transistor T1, the second electrode of the second transistor T2, and the second electrode of the fourth transistor T4, and a second electrode connected to the second electrode of the first transistor T1, the first electrode of the sixth transistor T6, the second electrode of the eighth transistor T8, and the second electrode of the second capacitor C2. The first electrode of the first capacitor C1 may receive the data voltage VDATA from the second transistor T2 and store the same.

The second capacitor C2 may include a first electrode connected to the second driving voltage line 179 and a second electrode connected to the second electrode of the first transistor T1, the first electrode of the sixth transistor T6, the second electrode of the eighth transistor T8, and the second electrode of the first capacitor C1. The second capacitor C2 may maintain the voltages at the second electrode of the first transistor T1 and the second electrode of the first capacitor C1. Depending on embodiments, the first electrode of the second capacitor C2 may be connected to the first driving voltage line 172, or the second capacitor C2 may be omitted.

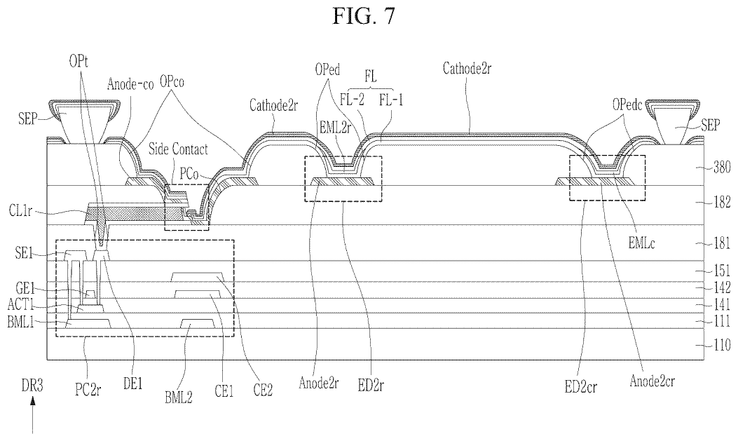

The light-emitting device LED may include an anode connected to the first driving voltage line 172 and receiving the first driving voltage ELVDD, and a cathode connected to the first electrode of the fifth transistor T5 and the second electrode of the seventh transistor T7. The cathode of the light-emitting device LED may pass through the fifth transistor T5 and is connected to the first transistor T1. The light-emitting device LED may be disposed between the pixel driver and the first driving voltage ELVDD, the same current as the current may flow to the first transistor T1 of the pixel driver flows, and luminance emitting according to the size of the corresponding current may be determined. The light-emitting device LED may include an emission layer including at least one of an organic light emitting material and an inorganic light emitting material between the anode and the cathode. A detailed stacked structure of the light-emitting device LED according to an embodiment may be like what is shown in FIG. 7.

The pixel according to an embodiment of FIG. 3 may perform a compensation operation for sensing a change of the characteristic (a threshold voltage) of the first transistor T1 and may display constant displaying luminance irrespective of the change of the characteristic of the first transistor T1.

Referring to FIG. 3, the light-emitting device LED may be disposed between the first electrode of the first transistor T1 and the first driving voltage line 172. The pixel may also be referred to as an inverted pixel to distinguish it from the pixel in which the light-emitting device LED is disposed between the first transistor T1 and the second driving voltage ELVSS. The light-emitting device may display luminance according to the size of the current flowing on the current path connected to the second driving voltage ELVSS from the first driving voltage ELVDD through the first transistor T1, and the displayed luminance may increase as the current increases. Regarding the inverted pixel structure of FIG. 3, the first electrode of the first transistor T1 may be connected to the light-emitting device LED and may be separated from the second electrode (source electrode) of the first transistor T1 so in case that the voltages at the respective portions of the pixel driver are changed, the voltage at the second electrode (source electrode) of the first transistor T1 may not be changed. In detail, in case that the sixth transistor T6 is turned on, the voltage at the second electrode of the first capacitor C1 may be reduced and the voltage at the first electrode of the first capacitor C1 may be reduced so the output current supplied by the first transistor T1 may be reduced, and the problem that the output current of the first transistor T1 is reduced may be removed in the embodiment. This will be described in detail while describing the operation of FIG. 2.

The embodiment of FIG. 3 describes that one pixel P includes eight transistors T1 to T8 and two capacitors (a first capacitor C1 and a second capacitor C2), and without being limited thereto, it may include more capacitors or transistors, or some capacitors or transistors may be omitted, depending on embodiments.

The circuit structure of the pixel according to an embodiment has been described with reference to FIG. 3.

A waveform of a signal applied to a pixel of FIG. 3, and a corresponding pixel operation will now be described with reference to FIG. 4.

FIG. 4 is a schematic waveform diagram of signals applied to a pixel of FIG. 3.

Referring to FIG. 4, the signal applied to the pixel may cover an initialization section, a compensation section, a writing section, and a light emitting section.

For the light emitting section, the light-emitting device LED may emit light, and a gate-on voltage (a high-level voltage) may be applied to a first light emitting signal EM1, and the fifth transistor T5 and the sixth transistor T6 may be turned on. The first scan signal GW, the second scan signal GC, the third scan signal GR, and the fourth scan signal GI may apply a gate-off voltage (a low-level voltage). As a result, a current path in order of the first driving voltage ELVDD, the light-emitting device LED, the fifth transistor T5, the first transistor T1, the sixth transistor T6, and the second driving voltage ELVSS may be formed. The size of the current flowing on the current path may be determined according to a turned-on degree of the channel of the first transistor T1, and the turned-on degree of the channel of the first transistor T1 is determined by the voltage at the gate electrode (or the first electrode of the first capacitor C1) of the first transistor T1. Therefore, as the output current generated according to the voltage at the gate electrode of the first transistor T1 flows along the current path including the light-emitting device LED, the light-emitting device LED may emit light. FIG. 4 shows the light emitting section in which the light emitting signal applies the gate-on voltage (a low-level voltage) as a brief occurrence, but in actuality, the light emitting section has the longest time. However, the light emitting section performs a simple operation as described above so it is simply shown in FIG. 4.

As the first light emitting signal EM1 may be changed to the gate-off voltage (a low-level voltage), the light emitting section ends and the initialization section may start.

Referring to FIG. 4, for the initialization section, the third scan signal GR may be changed to the gate-on voltage (a high-level voltage), and the fourth scan signal GI may be changed to the gate-on voltage (a high-level voltage). Here, the first scan signal GW, the second scan signal GC, and the first light emitting signal EM1 may apply the gate-off voltage (a low-level voltage).

The fourth transistor T4 connected to the third scan signal GR changed to the gate-on voltage (a high-level voltage) and applied may be turned on, and the reference voltage Vref may be transmitted to the gate electrode of the first transistor T1 and the first electrode of the first capacitor C1 and may be initialized. Here, the reference voltage Vref may have a voltage value for turning on the first transistor T1.

The fourth scan signal GI may be changed to the gate-on voltage (high-level voltage) and may be applied to turn on the eighth transistor T8, and as a result, the second electrode of the first transistor T1, the second electrode of the sixth transistor T6, the second electrode of the first capacitor C1, and the second electrode of the second capacitor C2 may be initialized with the first initialization voltage Vint.

The fourth scan signal GI may be changed to the gate-off voltage (low-level voltage), the initialization section may end, and the compensation section may start.

Referring to FIG. 4, for the compensation section, the third scan signal GR may maintain the gate-on voltage (high-level voltage), and the second scan signal GC may be changed to the gate-on voltage (high-level voltage). In this instance, the first scan signal GW, the fourth scan signal GI, and the first light emitting signal EM1 may apply the gate-off voltage (low-level voltage).

As the reference voltage Vref may be continuously transmitted to the gate electrode of the first transistor T1 and the first electrode of the first capacitor C1 through the turned-on fourth transistor T4, the third transistor T3 and the seventh transistor T7 may be turned on by the second scan signal GC of the additionally applied gate-on voltage (high-level voltage), and the second initialization voltage Vcint may be transmitted to the first electrode of the first transistor T1 and the cathode of the light-emitting device LED. In this instance, the first transistor T1 may have a turned-on state by the reference voltage Vref, and a value (Vgs) of the first transistor may be equal to a threshold voltage (Vth) value of the first transistor T1. Here, the value (Vgs) may be obtained by subtracting the voltage at the second electrode (source electrode) of the first transistor T1 from the voltage at the gate electrode so the voltage value at the second electrode (source electrode) of the first transistor T1 has the voltage value Vref-Vth that is lower than the voltage at the gate electrode by the threshold voltage (Vth) of the first transistor T1. The turned-on seventh transistor T7 may change the voltage level of the cathode to the first driving voltage ELVDD to initialize the voltage at the cathode with the first driving voltage ELVDD, and remove the charges remaining at the cathode to remove the problem of failing to display black.

Referring to FIG. 4, the second scan signal GC may be changed to the gate-off voltage (low-level voltage), the third scan signal GR may be changed to the gate-off voltage (low-level voltage), and the writing section may start.

For the writing section, the first scan signal GW may apply the gate-on voltage (high-level voltage). Here, the section for the first scan signal GW to be maintained at the gate-on voltage may be (1H). The section (1H) represents one horizontal period, and the one horizontal period may correspond to one horizontal synchronizing signal (Hsync). The section (1H) may signify a time for applying the gate-on voltage to a scan line in a next row after applying the gate-on voltage to a scan line. For the writing section, the second scan signal GC, the third scan signal GR, the first light emitting signal EM1, and the first light emitting signal EM1 may apply the gate-off voltage (low-level voltage).

For the writing section, the second transistor T2 for applying the gate-on voltage (high-level voltage) may be turned on, and other transistors may be turned off. As a result, the data voltage VDATA may enter the pixel and may be applied to the gate electrode of the first transistor T1 and the first electrode of the first capacitor C1. The voltage value at the second electrode of the first transistor T1 has the voltage value Vref-Vth that is lower than the voltage at the gate electrode by the threshold voltage (Vth) of the first transistor T1 in a like way of the compensation section.

The third transistor T3 and the fifth transistor T5 may be turned off so the first electrode of the first transistor T1, the first driving voltage line 172, and the light-emitting device LED are electrically separated.

Referring to FIG. 4, the first light emitting signal EM1 may be changed to the gate-on voltage (high-level voltage), and the light emitting section may start. Here, the first scan signal GW, the second scan signal GC, the third scan signal GR, and the fourth scan signal GI may apply the gate-off voltage (low-level voltage).

The fifth transistor T5 and the sixth transistor T6 may be turned on by the first light emitting signal EM1, and a current path in order of the first driving voltage ELVDD, the light-emitting device LED, the fifth transistor T5, the first transistor T1, the sixth transistor T6, and the second driving voltage ELVSS may be formed. The size of the current flowing on the current path may be determined by the turned-on degree of the first transistor T1, and the turned-on degree of the first transistor T1 may be determined according to the size pf the data voltage VDATA applied to the gate electrode. The light-emitting device LED may display different brightness according to the size of the current (I_{OLED}) flowing on the current path.

In case that the light emitting section starts, and the sixth transistor T6 may be turned on, the voltages at the second electrode of the first capacitor C1 and the second electrode of the first transistor T1 may be changed to the second driving voltage ELVSS. In case that the voltage value at the second electrode of the first capacitor C1 is changed, the voltage value at the first electrode of the first capacitor C1 may be changed. A voltage variation value at the first electrode of the first capacitor C1 may be equal to the voltage value at the second electrode of the first capacitor C1.

For the writing section, the voltage value at the second electrode of the first transistor T1 and the second electrode of the first capacitor C1 may have the value Vref-Vth obtained by subtracting the threshold voltage (Vth) of the first transistor T1 from the reference voltage value Vref, so in case that the writing section changes to the light emitting section, the variation of the voltage at the second electrode of the first capacitor C1 and the variation (ΔV) of the voltage at the first electrode of the first capacitor C1 are given in Equation 1:

ΔV=V_{ELVSS}−(V_{ref}−Vₜₕ) [Equation 1]

Here, V_{ref} may be a voltage value of the reference voltage Vref, Vₜₕ may be a threshold voltage value of the first transistor T1, and (V_{ELVSS}) may be a voltage value of the second driving voltage ELVSS.

In this instance, the current (I_{OLED}) flowing to the light-emitting device LED for the light emitting section may be obtained as in Equation 2:

I_{OLED}=k/2×(Vgs−Vₜₕ)²

=k/2×[(V_{data}+ΔV−V_{ELVSS})−Vₜₕ]²

=k/2×[(V_{data}+(V_{ELVSS}−V_{ref}+Vₜₕ)−V_{ELVSS})−Vₜₕ]²

=k/2×(V_{data}−V_{ref})² [Equation 2]

Here, k may be a constant, (V_{data}) may be a voltage value of the data voltage, V_{ref} may be a voltage value of the reference voltage (V_{ref}), (Vₜₕ) may be a threshold voltage value of the first transistor T1, (V_{ELVSS}) may be a voltage value of the second driving voltage ELVSS, (Vgs) may be a voltage difference between the gate electrode and the second electrode of the first transistor T1, and ΔV uses a value of Equation 1.

Therefore, the value of the current (I_{OLED}) flowing to the light-emitting device LED may be determined by the value of the data voltage VDATA and the value of the reference voltage V_{ref}, and may have a value that has no connection with the threshold voltage (Vₜₕ) of the first transistor T1 so it has an advantage of generating a constant output current (I_{OLED}) in case that the characteristic of the first transistor T1 is changed.

For the light emitting section, the second driving voltage ELVSS may be applied and the voltage variation (ΔV) generated to the gate electrode may be removed as expressed in Equation 1 so there is no need to consider the voltage variation (ΔV), and the value of the data voltage VDATA and the reference voltage V_{ref} are to be considered, and the current is not changed according to the characteristic of the first transistor T1 as an advantage.

The voltage value of the first driving voltage ELVDD is set to be greater than the value obtained by subtracting the threshold voltage value of the first transistor T1 from the voltage value of the reference voltage V_{ref}, and the voltage value of the second driving voltage ELVSS may be set to be less than the value obtained by subtracting the threshold voltage value of the first transistor T1 from the voltage value of the reference voltage V_{ref}.

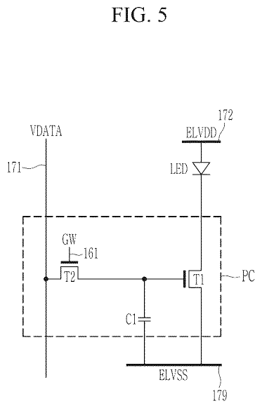

The operation according to the pixel of FIG. 3 and the waveform of FIG. 4 has been described in the above. A circuit structure of the light-emitting devices ED1 and ED2 and the pixel drivers PC1 and PC2 according to another embodiment will now be described with reference to FIG. 5.

FIG. 5 is a schematic diagram of an equivalent circuit of a pixel included in a light emitting display device according to another embodiment.

Referring to FIG. 5, the pixel may include a light-emitting device LED and a pixel driver for driving the same. The pixel driver may include all the elements exclusive of the light-emitting device LED, and the pixel driver may include a first transistor T1, a second transistor T2, and a first capacitor C1.

The pixel driver may be connected to the first scan line 161 for applying the first scan signal GW and the data line 171 for applying the data voltage VDATA. The pixel may be connected to the first driving voltage line 172 for applying the driving voltage ELVDD (a first driving voltage) and a second driving voltage line 179 for applying a low driving voltage ELVSS (a second driving voltage).

The circuit structure of the pixel will now be described with the focus on the respective elements (transistors, capacitors, and light-emitting devices) included in the pixel.

The first transistor T1 (or a driving transistor) may include a gate electrode connected to the first electrode of the first capacitor C1 and the second electrode of the second transistor T2, a first electrode (input-side electrode) connected to the cathode of the light-emitting device LED, and a second electrode (output-side electrode) for receiving the second driving voltage ELVSS.

The turned-on degree of the first transistor T1 may be determined according to the voltage at the gate electrode, and the size of the current flowing to the second electrode of the first transistor T1 from the first electrode according to the turned-on degree. The current flowing to the second electrode of the first transistor T1 from the first electrode may be equivalent to the current flowing to the light-emitting device LED and it may also be referred to as a light emitting current. Here, the first transistor T1 may be an n-type transistor, and the greater light emitting current may flow as the voltage of the gate electrode increases. In case that the light emitting current is large, the light-emitting device LED may display high luminance.

The second transistor T2 (a data input transistor) may include a gate electrode connected to the first scan line 161 for applying the first scan signal GW, a first electrode (input-side electrode) connected to the data line 171 for applying the data voltage VDATA, and a second electrode (output-side electrode) connected to the first electrode of the first capacitor C1 and the gate electrode of the first transistor T1. The second transistor T2 may input the data voltage VDATA to the pixel according to the first scan signal GW to transmit the same to the gate electrode of the first transistor T1 and store the same in the first electrode of the first capacitor C1.

All the transistors may be n-type transistors, and the transistors may be respectively turned on in case that the voltage at the gate electrode is a high-level voltage, and they may be turned off in case that it is a low-level voltage. The semiconductor layers included in the respective transistors may use polycrystalline silicon semiconductors or oxide semiconductors, and may additionally use amorphous semiconductors or monocrystalline semiconductors.

Depending on embodiments, the semiconductor layers included in the respective transistors may further include overlapping layers (or additional gate electrodes) for overlapping the semiconductor layers, and the characteristic of the transistors may be changed by applying voltages to the overlapping layers, and displaying quality of the pixel.

The first capacitor C1 may include a first electrode connected to the gate electrode of the first transistor T1 and the second electrode of the second transistor T2 and a second electrode for receiving the second driving voltage ELVSS. The first electrode of the first capacitor C1 may receive the data voltage VDATA from the second transistor T2 and store the same. Depending on embodiments, the second electrode of the first capacitor C1 may receive the first driving voltage ELVDD.

The light-emitting device LED may include an anode connected to the first driving voltage line 172 and receiving the first driving voltage ELVDD and a cathode connected to the first electrode of the first transistor T1. The light-emitting device LED may be disposed between the pixel driver and the first driving voltage ELVDD, the same current as the current flowing to the first transistor T1 of the pixel driver flows, and the luminance emitting according to the size of the corresponding current may be determined. The light-emitting device LED may include an emission layer including at least one of the organic light emitting material and the inorganic light emitting material between the anode and the cathode. A detailed stacking structure of the light-emitting device LED according to an embodiment may be like as is shown in FIG. 7.

Referring to FIG. 5, the light-emitting device LED may be disposed between the first electrode of the first transistor T1 and the first driving voltage line 172. The pixel may also be referred to as an inverted pixel to distinguish it from the pixel in which the light-emitting device LED is disposed between the first transistor T1 and the second driving voltage ELVSS. The light-emitting device may display luminance according to the size of the current flowing on the current path connected to the second driving voltage ELVSS from the first driving voltage ELVDD through the first transistor T1, and the displayed luminance may increase as the current increases.

FIG. 5 shows that one pixel P may include two transistors T1 and T2 and one capacitor (first capacitor C1) according to an embodiment, and without being limited thereto, the pixel P may include additional capacitors or transistors depending on embodiments.

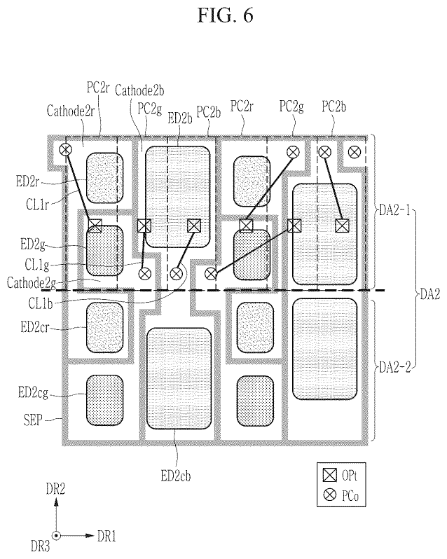

In the below, multiple second pixels may be formed in the second display area DA2, and a connection relationship between multiple light-emitting devices and a second pixel driver according to an embodiment will now be described with reference to FIG. 6.

FIG. 6 is a schematic top plan view of a connection between a pixel driver and a light-emitting device according to an embodiment.

FIG. 6 shows part of the second display area DA2, and a second-1 display area DA2-1 and a second-2 display area DA2-2 may be distinguished from each other with respect to the first direction DR1. The second display area DA2 shown in FIG. 6 may be the second display area DA2 disposed in an opposite direction of the second direction DR2 of the first display area DA1, for example, on a lower side thereof in FIG. 1, and the first display area DA1 may be disposed on an upper side in the second direction DR2 in FIG. 6.

For example, referring to FIG. 6, the second display area DA2 may be divided into two regions by a dotted line, and a second pixel driver PC2 may be disposed in the second-1 display area DA2-1 disposed on the upper side in the second direction DR2, and the second light-emitting device ED2 and the second pixel driver PC2 may overlap each other in the second-1 display area DA2-1 in a plan view. Not the second pixel driver PC2 but the peripheral driver DR of FIG. 2 (not shown) may be disposed in the second-2 display area DA2-2 disposed on the lower side in the second direction DR2. The second light-emitting device ED2 and the second pixel driver PC2 may not overlap each other in the second-2 display area DA2-2 in a plan view. Here, the light-emitting device may correspond to emission layers EML2r and EMLc of FIG. 7 disposed in openings OPed and OPedc of FIG. 7 of a pixel defining layer 380 of FIG. 7. Therefore, the emission layer EMLc of FIG. 7 disposed in the opening OPedc of FIG. 7 of the pixel defining layer 380 of FIG. 7 and the second pixel driver PC2 may not overlap each other in the second-2 display area DA2-2 in a plan view. The emission layer EML2r of FIG. 7 disposed in the opening OPed of FIG. 7 of the pixel defining layer 380 of FIG. 7 and the second pixel driver PC2 may overlap each other in the second-1 display area DA2-1 in a plan view. The emission layer disposed in the opening of the pixel defining layer 380 of FIG. 7 and the first pixel driver PC1 may overlap each other in the first display area DA1 in a plan view.

Light may be emitted by the second light-emitting device ED2 in the second display area DA2 of FIG. 6, and the second pixel driver PC2, the second light-emitting device ED2, and the peripheral driver may be disposed therein. The second pixel driver PC2 may be electrically connected to the second light-emitting device ED2, and the second pixel driver PC2 may supply the current to the second light-emitting device ED2. The region that emits light by the second light-emitting device ED2 may correspond to the second display area DA2. The second light-emitting device ED2 disposed in the second display area DA2 may be divided into second-1 light-emitting devices ED2r, ED2g, and ED2b (also referred to as main light-emitting devices or second main light-emitting devices) disposed on the second pixel driver PC2, and second-2 light-emitting devices ED2cr, ED2cg, and ED2cb (also referred to as additional light-emitting devices) disposed on the peripheral driver such as a scan signal generator.

In detail, the second display area DA2 of FIG. 6 may include second pixel drivers PC2r, PC2g, and PC2b and second-1 light-emitting devices ED2r, ED2g, and ED2b disposed in the second-1 display area DA2-1, and further may include second-2 light-emitting devices ED2cr, ED2cg, and ED2cb disposed in the second-2 display area DA2-2. Here, r, g, and b may signify red (R), green (G), and blue (B), and a second pixel driver, a second main light-emitting device, and an additional light-emitting device displaying a same color may be electrically connected to each other.

FIG. 6 shows second pixel drivers PC2r, PC2g, and PC2b with dotted lines, and they may have a circuit structure as shown in FIG. 3 or FIG. 5. The second pixel drivers PC2r, PC2g, and PC2b may be connected to at least one side of the cathode connecting lines CL1r, CL1g, and CL1b through a contact hole OPt, and other sides of the cathode connecting lines CL1r, CL1g, and CL1b may be electrically connected to the cathodes Cathode2r, Cathode2g, and Cathode2b of the second-1 light-emitting devices ED2r, ED2g, and ED2b through a contact hole PCo.

Referring to FIG. 6, the contact hole OPt that connects the second pixel drivers PC2r, PC2g, and PC2b and the cathode connecting lines CL1r, CL1g, and CL1b may be arranged in the first direction DR1. The contact hole PCo that connects the cathode connecting lines CL1r, CL1g, and CL1b and the cathodes Cathode2r, Cathode2g, and Cathode2b, and in detail, the contact holes PCo that connects the cathode connecting lines CL1r, CL1g, and CL1b and the cathodes Cathode2r, Cathode2g, and Cathode2b through an auxiliary connecting electrode Anode-co of FIG. 7 may be disposed to be adjacent to each other in the first direction DR1.

The cathodes Cathode2r, Cathode2g, and Cathode2b (also referred to as main cathodes) of the second-1 light-emitting devices ED2r, ED2g, and ED2b may be respectively distinguished by the separator SEP, and extend to the second-2 display area DA2-2 so they may function as the cathodes of the second-2 light-emitting devices ED2cr, ED2cg, and ED2cb. The respective cathodes Cathode2r, Cathode2g, and Cathode2b separated from each other may be distinguished into a portion disposed in the second-1 display area DA2-1, a portion disposed in the second-2 display area DA2-2, and a portion that connects the two portions. In detail, the integrally formed cathodes Cathode2r, Cathode2g, and Cathode2b may include a first portion overlapping emission layers of the second-1 light-emitting devices ED2r, ED2g, and ED2b in a plan view, a second portion overlapping an emission layer of the second-2 display area DA2-2 in a plan view, and a connector that connects the first portion and the second portion. Here, the connector may have a relatively narrow width compared to the other portions, and the width of the connector may be the width of the direction that is perpendicular to the direction that goes to the second portion from the first portion, for example, the first direction DR1 of FIG. 6. Respective portions of the cathodes Cathode2r, Cathode2g, and Cathode2b may be surrounded by one separator SEP, and at least some of the cathodes Cathode2r, Cathode2g, and Cathode2b may overlap the separator SEP in a plan view.

As a result, currents output by the second pixel drivers PC2r, PC2g, and PC2b may be transmitted to the cathodes Cathode2r, Cathode2g, and Cathode2b of the second-1 light-emitting devices ED2r, ED2g, and ED2b and the second-2 light-emitting devices ED2cr, ED2cg, and ED2cb so that the second-1 light-emitting devices ED2r, ED2g, and ED2b and the second-2 light-emitting devices ED2cr, ED2cg, and ED2cb may emit light.

Referring to FIG. 6, the separator SEP may traverse among the three contact holes PCo on a portion where the three contact holes PCo are adjacent in the first direction DR1 so that the cathodes Cathode2r, Cathode2g, and Cathode2b connected through the three contact holes PCo may be electrically separated. The separator SEP may be bent around the contact holes PCo.

Referring to FIG. 6, respective light-emitting devices ED2r, ED2g, ED2b, ED2cr, ED2cg, and ED2cb are shown, and the corresponding positions may correspond to the regions in which the emission layers EML2r and EMLc of FIG. 7 included in the respective light-emitting devices ED2r, ED2g, ED2b, ED2cr, ED2cg, and ED2cb are disposed, or they may correspond to the openings OPed and OPedc of FIG. 7 of the pixel defining layer 380 of FIG. 7 or the respective light emitting regions.

The respective cathodes Cathode2r, Cathode2g, and Cathode2b may be electrically separated from each other, and may be separated by the separator SEP. The separator SEP may correspond to a portion marked in gray. The separator SEP may have a planar shape surrounding the respective cathodes Cathode2r, Cathode2g, and Cathode2b, and may separate the adjacent cathodes Cathode2r, Cathode2g, and Cathode2b. As shown in FIG. 7, the respective separators SEP may protrude upward and may be reversely tapered. For example, the cathodes having a reversely tapered side wall and disposed on respective sides of the separator SEP may be electrically separated from each other.

According to the above-noted structure, the second light-emitting device ED2 may be disposed in the region in which the peripheral driver is formed so the display area DA having an extended area may be formed. Depending on embodiments, one pixel driver may be connected to at least one scan line so as to generate an accurate current and provide it to the light-emitting device, and in this instance, the area of the scan signal generator may be increased. However, in an embodiment according to the disclosure, the second light-emitting device ED2 may be disposed on the peripheral driver such as the scan signal generator so as to be included in the display area DA and prevent the display area DA from being reduced, and thereby allow the bigger display area DA.

One of the second-2 light-emitting devices ED2cr, ED2cg, and ED2cb may be connected to one of the second pixel drivers PC2r, PC2g, and PC2b in an embodiment of FIG. 6, and depending on embodiments, two or more second-2 light-emitting devices ED2cr, ED2cg, and ED2cb may be connected to one of the second pixel drivers PC2r, PC2g, and PC2b.

The second display area DA2 shown in FIG. 6 may be the second display area DA2 disposed in an opposite direction of the second direction DR2 of the first display area DA1, for example, on the lower side in FIG. 1. However, the second display area DA2 with a similar structure to FIG. 6 may be disposed in another second display area DA2 shown in FIG. 1. In this instance, the second-2 display area DA2-2 may be disposed outside the second-1 display area DA2-1, and their connection relationship may be the same as what is shown in FIG. 6.

A planar structure of FIG. 6 will now be described in detail in connection with the cross-sectional structure of FIG. 7.

FIG. 7 is a schematic cross-sectional view of a connection of a light-emitting device according to an embodiment of FIG. 6.

FIG. 7 generally shows a red second-1 light-emitting device ED2r and a second-2 light-emitting device ED2cr, and the lower second pixel driver may be the red second pixel driver PC2r.

FIG. 7 shows a transistor included in the second pixel driver PC2r disposed on lower portions of the planarization layers 181 and 182. Here, the light-emitting device described with reference to FIG. 6 may correspond to the planar structure of the emission layer disposed in the opening of the pixel defining layer 380, and the light-emitting device may further include an anode and a cathode disposed at the upper portion and the lower portion of the emission layer. The anode may be disposed at the lower portion or the upper portion of the emission layer, and the cathode may be disposed on the opposite side of the anode. Therefore, the anode and the cathode may be referred to as the first electrode and the second electrode. The first electrode, the pixel defining layer, an intermediate layer (including the emission layer), and the second electrode may be referred to as a light-emitting device layer, and the conductive layer, the semiconductor layer, and the insulating layer disposed on the lower portion of the light-emitting device layer and configuring the transistor and the capacitors may be referred to as a driving element layer in a cross-sectional view.

A structure from the substrate 110 to the planarization layers 181 and 182, for example, the structure of the driving element layer will now be described.

The first substrate 110 may include a material such as glass that is rigid and is not bent, or may include a flexible material such as plastic or polyimide that is bent. The flexible substrate may have a structure in which the polyimide and a barrier layer made of an inorganic insulating material are repeatedly formed.

Lower shielding layers BML1 and BML2 including metals may be disposed on the first substrate 110. The lower shielding layer BML1 may overlap a channel of the transistor, and the lower shielding layer BML2 may overlap the capacitor.

The first substrate 110 and the lower shielding layers BML1 and BML2 may be covered by a buffer layer 111. The buffer layer 111 may prevent permeation of impurities into the first semiconductor layer ACT1, and may be an inorganic insulating layer including a silicon oxide (SiOx), a silicon nitride (SiNx), or a silicon oxynitride (SiOₓN_{y}).

A first semiconductor layer ACT1 made of an oxide semiconductor or a polycrystalline semiconductor may be disposed on the buffer layer 111. The first semiconductor layer ACT1 may include a channel of the polycrystalline silicon transistor including a driving transistor and a first region and a second region disposed on respective sides of the channel. The polycrystalline silicon transistor may be a driving transistor and other switching transistors. The respective sides of the channel of the first semiconductor layer ACT1 may have regions that have the characteristic of conductive layers by plasma processing or doping, and may function as the first electrode and the second electrode of the transistor.

A first gate insulating layer 141 may be disposed on the first semiconductor layer ACT1. The first gate insulating layer 141 may be an inorganic insulating layer including a silicon oxide (SiOx), a silicon nitride (SiNx), or a silicon oxynitride (SiOₓN_{y}).

A first gate conductive layer including a gate electrode GE1 of the polycrystalline silicon transistor and a first storage electrode CE1 that is one electrode of the first capacitor C1 may be disposed on the first gate insulating layer 141. Depending on embodiments, the first storage electrode CE may be integrally formed with the gate electrode GE1 of the driving transistor. Scan lines or light emitting control lines in addition to the gate electrode GE1 of the polycrystalline silicon transistor may be formed on the first gate conductive layer. The first gate conductive layer may include a metal such as copper (Cu), molybdenum (Mo), aluminum (Al), titanium (Ti), and/or metal alloys thereof, and may be configured to be a single layer or a multilayer.

The exposed region of the first semiconductor layer may be made a conductor by forming the first gate conductive layer and performing plasma processing or a doping process. For example, the first semiconductor layer ACT1 covered by the gate electrode GE1 may not be made a conductor, and a portion of the first semiconductor layer ACT1 no covered by the gate electrode GE1 may have the same characteristic as the conductive layer.

A second gate insulating layer 142 may be disposed on the first gate conductive layer and the first gate insulating layer 141. The second gate insulating layer 142 may be an inorganic insulating layer including a silicon oxide (SiOx), a silicon nitride (SiNx), or a silicon oxynitride (SiOₓN_{y}).

A second gate conductive layer including a second storage electrode CE2 that is one electrode of the first capacitor C1 may be disposed on the second gate insulating layer 142. The second gate conductive layer may include a metal such as copper (Cu), molybdenum (Mo), aluminum (Al), titanium (Ti), and/or metal alloys thereof, and may be configured to be a single layer or a multilayer.

A first interlayer insulating layer 151 may be disposed on the second gate conductive layer. The first interlayer insulating layer 151 may include an inorganic insulating layer including a silicon oxide (SiOx), a silicon nitride (SiNx), or a silicon oxynitride (SiOₓN_{y}), and depending on embodiments, the inorganic insulating material may be made thick.

A first data conductive layer including connecting electrodes SE1 and DE1 that may be connected to the first region and the second region of the first semiconductor layer ACT1 of the polycrystalline silicon transistor may be disposed on the first interlayer insulating layer 151. Referring to FIG. 7, the connecting electrode SE1 may be connected to the first region of the first semiconductor layer ACT1, and may be connected to the lower shielding layer BML1. The first data conductive layer may include a metal such as copper (Cu), molybdenum (Mo), aluminum (Al), titanium (Ti), and/or metal alloys thereof, and may be configured to be a single layer or a multilayer.

A first planarization layer 181 may be disposed on the first data conductive layer. The first planarization layer 181 may be an organic insulator including an organic material, and the organic material may include at least one material of a polyimide, a polyamide, an acryl resin, a benzocyclobutene, and a phenol resin. The contact hole OPt may be disposed in the first planarization layer 181, and the connecting electrode DE1 may be exposed by the contact hole OPt. The contact hole OPt may overlap part of the connecting electrode DE1 in a plan view.

A second data conductive layer including a cathode connecting line CL1r may be disposed on the first planarization layer 181. The second data conductive layer may include a data line or a first driving voltage line. The second data conductive layer may include a metal such as copper (Cu), molybdenum (Mo), aluminum (Al), titanium (Ti), and/or metal alloys thereof, and may be configured to be a single layer or a multilayer. The cathode connecting line CL1r is connected to the connecting electrode DE1 through the contact hole OPt disposed in the first planarization layer 181. Referring to FIG. 7, the cathode connecting line CL1r and the second data conductive layer may have a triple-layered structure, and the triple-layered structure may have a lower layer and an upper layer including titanium (Ti), and an intermediate layer including aluminum (Al) therebetween.

A second planarization layer 182 may be disposed on the second data conductive layer, and the second planarization layer 182 may be an organic insulator and may include at least one material of a polyimide, a polyamide, an acryl resin, benzocyclobutene, and a phenol resin. The contact hole PCo may be disposed in the second planarization layer 182, and the cathode connecting line CL1r may be exposed by the contact hole PCo. The contact hole PCo may overlap part of the cathode connecting line CL1r in a plan view.

Respective anodes Anode2r and Anode2cr of the light-emitting devices ED2r and ED2cr and an auxiliary connecting electrode Anode-co may be formed on the second planarization layer 182. Here, the auxiliary connecting electrode Anode-co may be made of the same material as the anodes Anode2r and Anode2cr.

The anode Anode2r (also referred to as a second main anode or a main anode) of the second-1 light-emitting device ED2r and the anode Anode2cr (also referred to as an additional anode) of the second-2 light-emitting device ED2cr may be electrically connected to the first driving voltage line 172 and receive the first driving voltage ELVDD.

The auxiliary connecting electrode Anode-co may be disposed near the contact hole PCo, and may support the cathode Cathode2r and the cathode connecting line CL1r to be electrically connected through the contact hole PCo. In case performing a wet etching to form the anode, particles of silver (Ag) may be reduced/precipitated around the third data conductive layer including exposed aluminum (Al), and defects may be generated in the following process so the particles of silver may not be generated and the defects may be removed by forming the auxiliary connecting electrode Anode-co that is an anode material on the corresponding portion. The embodiment that has no such defects may omit the auxiliary connecting electrode Anode-co in case that there is no problem in electrically connecting the cathode Cathode2r and the cathode connecting line CL1r.

The pixel defining layer 380 having openings OPed, OPedc and OPco for exposing the anodes Anode2r and Anode2cr and the auxiliary connecting electrode Anode-co and covering at least part of the anodes Anode2r and Anode2cr and the auxiliary connecting electrode Anode-co may be disposed on the anodes Anode2r and Anode2cr and the auxiliary connecting electrode Anode-co. The pixel defining layer 380 may be a black pixel defining layer made of a black organic material and preventing external light from being reflected to the outside, and depending on embodiments, it may be made of a transparent organic material. The openings OPed and OPedc for exposing the anodes Anode2r and Anode2cr in the pixel defining layer 380 may correspond to the light-emitting devices ED2r, ED2g, ED2b, ED2cr, ED2cg, and ED2cb in a plan view, and borders of the openings of the pixel defining layer 380 may correspond to the borders of the light-emitting devices ED2r, ED2g, ED2b, ED2cr, ED2cg, and ED2cb and/or the respective light emitting regions.

The separator SEP may be disposed on the pixel defining layer 380. The separator SEP may have a reversely tapered side wall so that the layer disposed on the upper portion of the separator SEP may be disconnected near the separator SEP. For example, a functional layer FL and the cathode Cathode2r disposed on the upper portion of the separator SEP may be electrically separated on the reversely tapered side wall, as shown in FIG. 7. The separator SEP may be made of the same material as the pixel defining layer 380, or may be made of a different material from the pixel defining layer 380 according to another process.

A first functional layer FL-1 may be disposed on the pixel defining layer 380 and the separator SEP, and the first functional layer FL-1 may be disconnected near the separator SEP.

The emission layers EML2r and EMLc are respectively disposed on the first functional layer FL-1, and also on the anodes Anode2r and Anode2cr exposed by the opening of the pixel defining layer 380.

A second functional layer FL-2 may be disposed on the first functional layer FL-1 and the emission layers EML2r and EMLc, and the second functional layer FL-2 may be disconnected near the separator SEP.

The first functional layer FL-1 and the second functional layer FL-2 may contact each other near a region in which the emission layers EML2r and EMLc are not disposed.

The cathode Cathode2r may be disposed on the second functional layer FL-2, and the respective cathodes Cathode2r may be separated from each other with respect to the separator SEP. A portion (also referred to as a main cathode) overlapping the emission layer EML2r from among the cathode Cathode2r may configure a cathode of the second-1 light-emitting device ED2r, and a portion (also referred to as an additional cathode) overlapping the emission layer EMLc from among the cathode Cathode2r may configure a cathode of the second-2 light-emitting device ED2cr. For example, the cathode of the second-1 light-emitting device ED2r and the cathode of the second-2 light-emitting device ED2cr are integrally formed into one cathode Cathode2r as shown in FIG. 7.

A combination of the functional layer FL and the emission layer may be referred to as an intermediate layer. The functional layer FL may include at least one of auxiliary layers such as an electron injection layer, an electron transport layer, a hole transport layer, or a hole injection layer, the first functional layer FL-1 disposed at the lower portions of the emission layers EML2r and EMLc may include a hole injection layer and/or a hole transport layer, and the second functional layer FL-2 disposed at the upper portions of the emission layers EML2r and EMLc may include an electron transport layer and/or an electron injection layer.

The second-1 light-emitting device ED2r may include a main cathode that is part of the anode Anode2r, the emission layer EML2r, and the cathode Cathode2r, and may further include a first functional layer FL-1 disposed between the anode Anode2r and the emission layer EML2r and a second functional layer FL-2 disposed between the emission layer EML2r and the main cathode.

The second-2 light-emitting device ED2cr may include an additional cathode that is another part of the anode Anode2cr, the emission layer EMLc, and the cathode Cathode2r, and may further include a first functional layer FL-1 disposed between the anode Anode2cr and the emission layer EMLc and a second functional layer FL-2 disposed between the emission layer EMLc and the additional cathode.

An end of the main cathode that is part of the cathode Cathode2r of the second-1 light-emitting device ED2r and at least part of the functional layer FL disposed below the end may overlap the auxiliary connecting electrode Anode-co, and may be electrically connected to the cathode connecting line CL1r through the contact hole PCo. In detail, in an embodiment of FIG. 7, the cathode connecting line CL1r and a portion of the cathode Cathode2r may be electrically connected by a side-contact method. For example, the intermediate layer including aluminum (Al) may be etched more than the lower layer and the upper layer including titanium (Ti) in the triple-layered structure of the cathode connecting line CL1r, and a portion of the cathode Cathode2r and the intermediate layer of the cathode connecting line CL1r may contact each other with the auxiliary connecting electrode Anode-co therebetween and may be electrically connected to each other. In this instance, the auxiliary connecting electrode Anode-co may be connected to the lower layer of the cathode connecting line CL1r. The side-contact method of FIG. 7 represents one of the electrically connecting methods according to an embodiment so many other electrically connecting methods are allowable depending on embodiments.

The cathode connecting line CL1r may be connected to the integrally formed cathode Cathode2r and may be electrically connected to the main cathode of the second-1 light-emitting device ED2r and the additional cathode of the second-2 light-emitting device ED2cr. Depending on embodiments, a spacer may be further formed on the pixel defining layer 380, and the spacer may have a tapered side wall to prevent the cathode from being disconnected.

FIG. 7 does not show the structure disposed on the cathode, but an encapsulation layer may be disposed thereon depending on embodiments. The encapsulation layer may include at least one inorganic film and at least one organic film, and may have a triple-layered structure including a first inorganic encapsulation layer, an organic encapsulation layer, and a second inorganic encapsulation layer. The encapsulation layer may protect the emission layers EML2r and EMLc from moisture or oxygen that may be input from the outside. Depending on embodiments, the encapsulation layer may include a structure in which inorganic layers and organic layers are sequentially further stacked.

Depending on embodiments, a sensing insulating layer and sensing electrodes may be disposed on the encapsulation layer to sense touches.

Depending on embodiments, a film including a polarizer may be attached to the encapsulation layer to reduce reflection of external light, or a color filter or a color converting layer may be further formed thereon to improve color quality. A light blocking layer may be disposed between the color filter and the color converting layer. Depending on embodiments, a layer on which a material (hereinafter, a reflection adjusting material) for absorbing light with a predetermined or selected wavelength from among external light may be further included. Depending on embodiments, the front side of the light emitting display device may be made flat by covering with the additional planarization layer (or the planarization layer).

The light emitting display device with the structure described with reference to FIG. 1 has been described, and the second display area DA2 may be disposed along an external side of the first display area DA1 in an embodiment of FIG. 1.

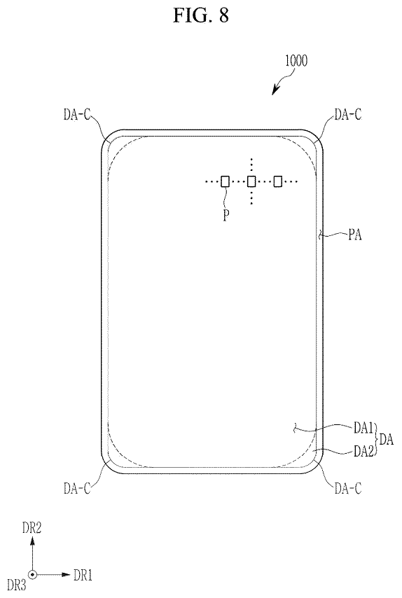

However, the second display area DA2 may be formed at a position that is different from what is shown in FIG. 1, and an embodiment thereof will now be described with reference to FIG. 8.

FIG. 8 is a schematic top plan view of a light emitting display device according to another embodiment.

The light emitting display device according to an embodiment of FIG. 8 may be different from an embodiment of FIG. 1 at least in that the second display area DA2 may be disposed at four corners DA-C and their peripheral areas. For example, the second display area DA2 may be disposed on a portion that corresponds to the corner of the first display area DA1.

FIG. 8 has an advantage of having the wider display area DA by reducing the non-display area formed at the corner DA-C of the light emitting display device and changing to the second display area DA2.

The embodiment of FIG. 2 to FIG. 7 may be applied to the light emitting display device according to an embodiment of FIG. 8. For example, part of the second display area DA2 disposed around the corner DA-C of FIG. 8 may overlap the peripheral driver as shown in FIG. 2. The embodiment of FIG. 3 to FIG. 7 may be applied to the light emitting display device.

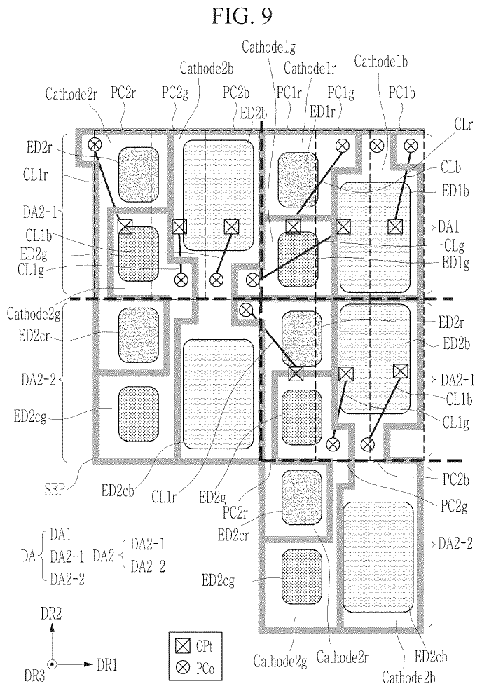

The corner DA-C of the second display area DA2 may have a curved shape, and this portion may, in case enlarged, have a layout of the light-emitting device as shown in FIG. 9.

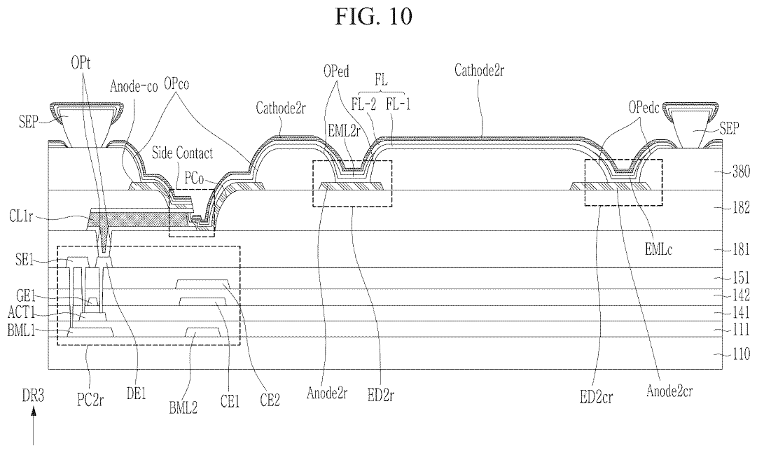

A planar and cross-sectional structure of the second display area DA2 having a curved border will now be described with reference to FIG. 9 and FIG. 10.

FIG. 9 is a schematic top plan view of a connection between a pixel driver and a light-emitting device according to an embodiment, and FIG. 10 is a schematic cross-sectional view of a connection of a light-emitting device according to an embodiment of FIG. 9.

FIG. 9 shows a border portion of the second display area DA2 and the non-display area, and it is found that the border marked with the dotted line between the second-1 display area DA2-1 and the second-2 display area DA2-2 may have a bent straight line shape so as to correspond to the border of the curve shape of the second display area DA2. The second display area DA2 shown in FIG. 9 may be disposed on the corner DA-C disposed on the bottom left from among the corners DA-C of FIG. 8.

FIG. 9 shows the first display area DA1 at the top right, and FIG. 9 shows the non-display area on the left and on the bottom. Referring to FIG. 9, one of the second pixel drivers PC2r, PC2g, and PC2b, one of the second-1 light-emitting devices ED2r, ED2g, and ED2b, and one of the second-2 light-emitting devices ED2cr, ED2cg, and ED2cb may be formed in a row in the second display area DA2. The number of the second pixel drivers PC2r, PC2g, and PC2b, the second-1 light-emitting devices ED2r, ED2g, and ED2b, and the second-2 light-emitting devices ED2cr, ED2cg, and ED2cb formed in the second display area DA2 may be plural according to the size of the peripheral driver DR of FIG. 2 (not shown) disposed in the second-2 display area DA2-2.

In detail, the second display area DA2 of FIG. 9 may include second pixel drivers PC2r, PC2g, and PC2b and second-1 light-emitting devices ED2r, ED2g, and ED2b disposed in the second-1 display area DA2-1, and additionally may include second-2 light-emitting devices ED2cr, ED2cg, and ED2cb disposed in the second-2 display area DA2-2.

The second pixel drivers PC2r, PC2g, and PC2b are marked with dotted lines, and may have circuit structures shown in FIG. 3 or FIG. 5. The second pixel drivers PC2r, PC2g, and PC2b may be respectively connected to a side of the cathode connecting lines CL1r, CL1g, and CL1b through the contact hole OPt, and other sides of the cathode connecting lines CL1r, CL1g, and CL1b may be electrically connected to the cathodes Cathode2r, Cathode2g, and Cathode2b of the second-1 light-emitting devices ED2r, ED2g, and ED2b through the contact holes PCo.

The contact holes OPt that connects the second pixel drivers PC2r, PC2g, and PC2b and the cathode connecting lines CL1r, CL1g, and CL1b may be arranged in the first direction DR1. The contact holes PCo that connects the cathode connecting lines CL1r, CL1g, and CL1b and the cathodes Cathode2r, Cathode2g, and Cathode2b, in detail, the three contact holes PCo that connects the cathode connecting lines CL1r, CL1g, and CL1b and the cathodes Cathode2r, Cathode2g, and Cathode2b through the auxiliary connecting electrode Anode-co of FIG. 10 may be adjacently disposed in the first direction DR1.

The cathodes Cathode2r, Cathode2g, and Cathode2b (also referred to as main cathodes) of the second-1 light-emitting devices ED2r, ED2g, and ED2b may be distinguished by the separator SEP, and may extend to the second-2 display area DA2-2 to thus function as the cathodes of the second-2 light-emitting devices ED2cr, ED2cg, and ED2cb. The respective separated cathodes Cathode2r, Cathode2g, and Cathode2b may be distinguished into a portion disposed in the second-1 display area DA2-1, a portion disposed in the second-2 display area DA2-2, and a portion that connects the two portions. In detail, the integrally formed cathodes Cathode2r, Cathode2g, and Cathode2b may include a first portion overlapping the emission layers of the second-1 light-emitting devices ED2r, ED2g, and ED2b in a plan view, a second portion overlapping the emission layer of the second-2 display area DA2-2 in a plan view, and a connector that connects the first portion and the second portion. Here, the connector may have a relatively smaller width than the other portions, and the width of the connector may be the width of the direction that is perpendicular to the direction facing the second portion at the first portion, for example, the first direction DR1 of FIG. 9. The respective portions of the cathodes Cathode2r, Cathode2g, and Cathode2b may be surrounded by the separator SEP, and at least one portion of the respective portions of the cathodes Cathode2r, Cathode2g, and Cathode2b may overlap the separator SEP in a plan view.

As a result, the currents output by the second pixel drivers PC2r, PC2g, and PC2b may be transmitted to the cathodes Cathode2r, Cathode2g, and Cathode2b of the second-1 light-emitting devices ED2r, ED2g, and ED2b and the second-2 light-emitting devices ED2cr, ED2cg, and ED2cb so that the second-1 light-emitting devices ED2r, ED2g, and ED2b and the second-2 light-emitting devices ED2cr, ED2cg, and ED2cb may emit light.

The separator SEP may be disposed traverse among the three contact holes PCo on the portion on which the three contact holes PCo are disposed in the first direction DR1 to electrically separate the cathodes Cathode2r, Cathode2g, and Cathode2b connected through the three contact holes PCo. The separator SEP may be bent near the contact holes PCo.

The adjacent second pixel drivers PC2r, PC2g, and PC2b may be disposed in different rows. For example, in case that the second pixel drivers PC2r, PC2g, and PC2b move by one row in the first direction DR1, there may be the second pixel drivers PC2r, PC2g, and PC2b disposed below by one row in a reverse direction of the second direction DR2. In case that the second-1 light-emitting devices ED2r, ED2g, and ED2b and the second-2 light-emitting devices ED2cr, ED2cg, and ED2cb move in the first direction DR1 by one row, there may be a light-emitting device disposed below by one row in the reverse direction of the second direction DR2.

The respective cathodes Cathode2r, Cathode2g, and Cathode2b may be electrically separated by the separator SEP marked in gray. The separator SEP may surround the cathodes Cathode2r, Cathode2g, and Cathode2b in a plan view, and may separate the adjacent cathodes Cathode2r, Cathode2g, and Cathode2b. As shown in FIG. 10, the respective separators SEP may protrude upward and may be reversely tapered. For example, they may have a reversely tapered side wall so the cathodes disposed on respective sides of the separator SEP may be electrically separated from each other.

According to the above-noted structure, as the second light-emitting device ED2 may be disposed in the region in which the peripheral driver is formed, the display area DA with the increased area may be formed. The border of the second display area DA2 may have the curved shape shown in FIG. 8 because of the planar structure of FIG. 9. For example, in case that the border portion of the corner DA-C of FIG. 8 is enlarged, the border of the second display area DA2 may have an alternate shape as shown in FIG. 9.

Referring to FIG. 9, the first display area DA1 may include first pixel drivers PC1r, PC1g, and PC1b marked with dotted lines and first light-emitting devices ED1r, ED1g, and ED1b. The first light-emitting devices ED1r, ED1g, and ED1b include cathodes Cathode1r, Cathode1g, and Cathode1b separated by the separator SEP. The first pixel drivers PC1r, PC1g, and PC1b may be connected to a side of cathode connecting lines CLr, CLg, and CLb through the contact hole OPt, and other sides of the cathode connecting lines CLr, CLg, and CLb may be electrically connected to the cathodes Cathode1r, Cathode1g, and Cathode1b of the first light-emitting devices ED1r, ED1g, and ED1b through the contact hole PCo.

Referring to FIG. 9, the three contact holes PCo disposed in the first display area DA1 may be adjacently disposed in the first direction DR1, and the separator SEP traverse among the three contact holes PCo so that the cathodes Cathode1r, Cathode1g, and Cathode1b connected through the three contact holes PCo may be electrically separated. The separator SEP may be bent around the contact holes PCo. Three additional contact holes PCo may extend in the first direction DR1 near the three shown contact holes PCo in the other first display area DA1 disposed in the first display area DA1 in the second direction DR2 shown in FIG. 9. As a result, the six contact holes PCo may be gathered and formed.

One of the second-2 light-emitting devices ED2cr, ED2cg, and ED2cb may be connected to one of the second pixel drivers PC2r, PC2g, and PC2b in an embodiment of FIG. 9, and two or more second-2 light-emitting devices ED2cr, ED2cg, and ED2cb may be connected to one of the second pixel drivers PC2r, PC2g, and PC2b depending on embodiments.

The above-described planar structure of FIG. 9 may have the cross-sectional structure of FIG. 10.

FIG. 10 generally shows the red second-1 light-emitting device ED2r and the second-2 light-emitting device ED2cr, and the second pixel driver at the lower portion may be the red second pixel driver PC2r.

The structure disposed at the lower portions of the planarization layers 181 and 182 in FIG. 10 may correspond to what is shown in FIG. 7. The cross-sectional structure according to an embodiment of FIG. 9 will now be described with the focus on the portions that are different from FIG. 7 in FIG. 10.

Referring to FIG. 10, a cathode Cathode2r may be disposed on the pixel defining layer 380 and the separator SEP, and on the second functional layer FL-2. The respective cathodes Cathode2r may be separated with respect to the separator SEP. A portion (hereinafter, a main cathode) of the cathode Cathode2r overlapping the emission layer EML2r may configure a cathode of the second-1 light-emitting device ED2r, and a portion (hereinafter, an additional cathode) of the cathode Cathode2r overlapping the emission layer EMLc may configure a cathode of the second-2 light-emitting device ED2cr. For example, the cathode of the second-1 light-emitting device ED2r and the cathode of the second-2 light-emitting device ED2cr may be integrally formed and are shown as one cathode Cathode2r in FIG. 10.

The second-1 light-emitting device ED2r may include the anode Anode2r, the emission layer EML2r, and the main cathode, for example, the portion of the cathode Cathode2r, and may further include a first functional layer FL-1 disposed between the anode Anode2r and the emission layer EML2r and a second functional layer FL-2 disposed between the emission layer EML2r and the main cathode.

The second-2 light-emitting device ED2cr may include the anode Anode2cr, the emission layer EMLc, and the additional cathode that is another portion of the cathode Cathode2r, and may further include a first functional layer FL-1 disposed between the anode Anode2cr and the emission layer EMLc and a second functional layer FL-2 disposed between the emission layer EMLc and the additional cathode.

The cathode connecting line CL1r may be connected to the integrally formed cathode Cathode2r and may be electrically connected to the main cathode of the second-1 light-emitting device ED2r and the additional cathode of the second-2 light-emitting device ED2cr.

Depending on embodiments, no spacer may be formed on the pixel defining layer 380, and the spacer may have a tapered side wall to prevent the cathode from being disconnected.

FIG. 10 shows no structure on the cathode, and an encapsulation layer may be disposed thereon depending on embodiments. The encapsulation layer may include at least one inorganic film and at least one organic film, and may have a triple-layered structure including a first inorganic encapsulation layer, an organic encapsulation layer, and a second inorganic encapsulation layer. The encapsulation layer may protect the emission layers EML2r and EMLc from moisture or oxygen that may be input from the outside. Depending on embodiments, the encapsulation layer may include a structure in which inorganic layers and organic layers are sequentially further stacked.

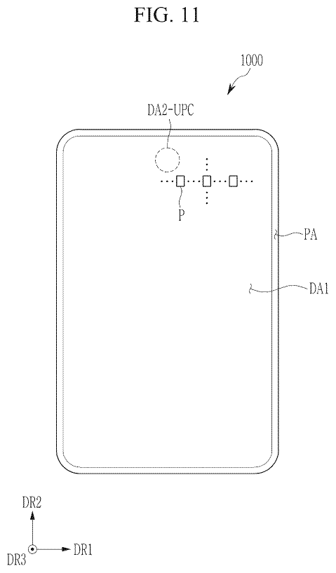

An embodiment has been described in which the non-display area in which the additional light-emitting device may be disposed near the display area may be changed to the display area and the display area may be increased, and the additional light-emitting device may be disposed at the upper portion of the peripheral driver for generating the signal for operating the pixel. However, the additional light-emitting device may be disposed on the outside of the display area, the upper portion of the peripheral driver, etc. An embodiment for disposing the additional light-emitting device in a component area DA2-UPC that corresponds to a camera disposed on a rear side will now be described with reference to FIG. 11 to FIG. 14. The component area may be referred to as a second display area including a light transmitting area, the second display area including a light transmitting area may be surrounded by the first display area, and the light transmitting area may provide light to the camera.

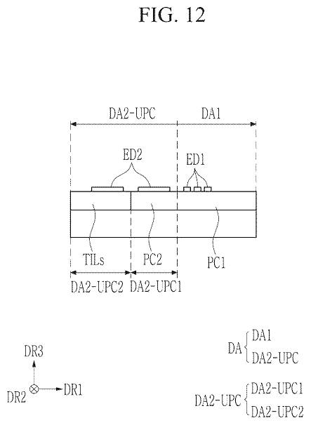

A schematic structure of the light emitting display device is described with reference to FIG. 11 and FIG. 12.

FIG. 11 is a schematic top plan view of a light emitting display device according to another embodiment, and FIG. 12 is a schematic cross-sectional view of a portion of FIG. 11.

The light emitting display device 1000 may include a component area DA2-UPC disposed in the first display area DA1 and surrounded by the first display area DA1.

The light emitting display device may include a light emitting display panel, and a camera (not shown) may be disposed on the rear side of the component area DA2-UPC of the light emitting display panel. Depending on embodiments, not the camera but a sensor may be disposed on the rear side of the component area DA2-UPC.

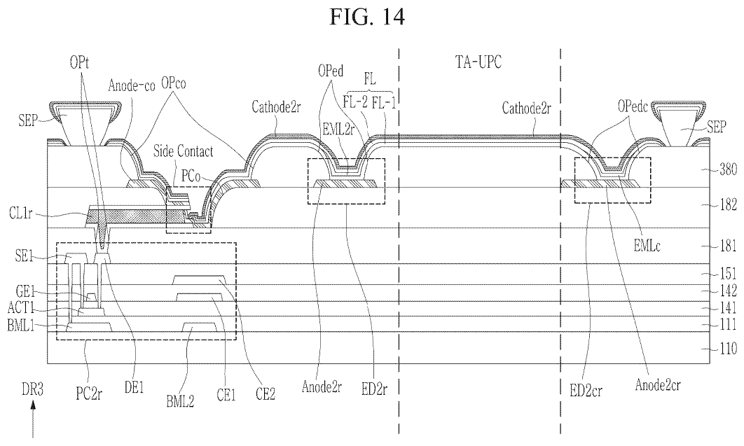

The component area DA2-UPC may include a region (also referred to as a light transmitting area (refer to TA-UPC of FIG. 14)) made of a transparent layer for transmitting light and a pixel (also referred to as a second component pixel) for displaying images. An opaque conductive layer or a semiconductor layer may not be disposed on the light transmitting area, and the light transmitting area may not block light in case that the layer including a light blocking material, for example, the pixel defining layer and/or a light blocking layer including an opening overlapping the position that corresponds to the component area DA2-UPC. The light transmitting area may have a transparent conductive layer and may include a cathode depending on embodiments, and a functional layer may be disposed below the cathode.

The structure of the first display area DA1 may be the same as what is shown in FIG. 2 so the structure of the component area DA2-UPC will now be described with reference to FIG. 12.

The component area DA2-UPC may include a second light-emitting device ED2 and a second pixel driver PC2.

The component area DA2-UPC may have a light transmitting area, it may emit light by the second light-emitting device ED2, and it may be divided into a second-1 component area DA2-UPC1 and a second-2 component area DA2-UPC2. The second pixel driver PC2 may be disposed in the second-1 component area DA2-UPC1, and the light transmitting area in which a transparent insulating layer TILs is disposed may be disposed in the second-2 component area DA2-UPC2. Here, the transparent insulating layer TILs may not include a semiconductor layer or a conductive layer but may be made of a transparent insulating layer so it may not block light. Depending on embodiments, the light transmitting area may be disposed in other regions in addition to the second-1 component area DA2-UPC1 and the second-2 component area DA2-UPC2.

In an embodiment of FIG. 12, the second light-emitting device ED2 for receiving the light emitting current from the second pixel driver PC2 may be disposed in the second-1 component area DA2-UPC1 and the second-2 component area DA2-UPC2. The second light-emitting device ED2 may be distinguished into a second light-emitting device ED2 disposed on the upper portion of the second pixel driver PC2 and a second light-emitting device ED2 disposed on the upper portion of the transparent insulating layer TILs. The second light-emitting device ED2 disposed on the transparent insulating layer TILs may configure the second-2 component area DA2-UPC2, and receive the light emitting current from at least part of the second pixel driver PC2 disposed in the second-1 component area DA2-UPC1. For example, the second pixel driver PC2 may be distinguished into a second pixel driver PC2 for transmitting outputs to the second light-emitting device ED2 configuring the second-1 component area DA2-UPC1 and a second pixel driver PC2 for transmitting outputs to the second light-emitting device ED2 configuring the second-2 component area DA2-UPC2. One second pixel driver PC2 may transmit an output current to the second light-emitting devices ED2, and at least one of the second light-emitting devices ED2 may be disposed in the second-2 component area DA2-UPC2 and may be disposed on the upper portion of the transparent insulating layer TILs. A remaining portion exclusive of the portion on which the second light-emitting device ED2 disposed on the transparent insulating layer TILs is disposed in the second-2 component area DA2-UPC2 may correspond to the light transmitting area.

Depending on embodiments, the number of the second component pixels per area may be less than the number of normal pixels per area included in the first display area DA1. As a result, a resolution of the second component pixels may be lower than a resolution of the normal pixels. One first pixel driver PC1 may be connected to one first light-emitting device ED1, and one second pixel driver PC2 may be connected to at least two second light-emitting devices ED2. The size of the first pixel driver PC1 may be equal to/different from the size of the second pixel driver PC2. For example, the second pixel driver PC2 may be bigger than the first pixel driver PC1.

Regarding the light emitting display device according to a comparative example, no additional pixels or light-emitting devices may be formed in the region in which the camera is disposed in the display area so the non-display area may be disposed in the display area, which is a drawback. However, in the embodiment of FIG. 12, the images may be displayed by disposing the pixels or the light-emitting devices in the component area DA2-UPC, so the non-display area is not disposed in the display area, which is an advantage.

The pixel of the light emitting display device according to an embodiment of FIG. 12 may have the pixel circuit shown in FIG. 3 or FIG. 5.

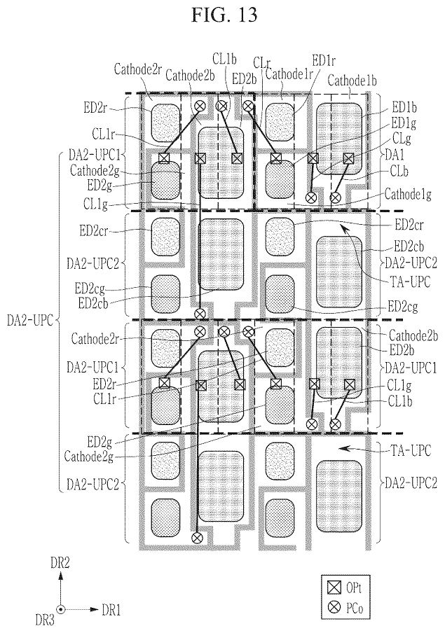

A detailed structure of the component area DA2-UPC will now be described according to an embodiment of FIG. 13 and FIG. 14.

A planar structure of the component area DA2-UPC will now be described with reference to FIG. 13.

FIG. 13 is a schematic top plan view of a connection between a pixel driver and a light-emitting device according to an embodiment.

In the embodiment of FIG. 13, the second pixel drivers PC2r, PC2g, and PC2b and the second-1 light-emitting devices ED2r, ED2g, and ED2b formed in the second-1 component area DA2-UPC1 and the second-2 light-emitting devices ED2cr, ED2cg, and ED2cb formed in the second-2 component area DA2-UPC2 may be shown together with the first display area DA1, and the light transmitting area TA-UPC may be formed in the portion in which the second-2 light-emitting devices ED2cr, ED2cg, and ED2cb are not disposed in the second-2 component area DA2-UPC2.

Referring to FIG. 13, the light transmitting area TA-UPC may be made transparent, and the camera disposed on the rear side may photograph/sense the front side of the light emitting display device through the light transmitting area TA-UPC.

The second pixel drivers PC2r, PC2g, and PC2b, and the second-1 light-emitting devices ED2r, ED2g, and ED2b and the second-2 light-emitting devices ED2cr, ED2cg, and ED2cb electrically connected to the second pixel drivers PC2r, PC2g, and PC2b may be formed in a region that is not the light transmitting area TA-UPC in the component area DA2-UPC.

The second pixel drivers PC2r, PC2g, and PC2b are shown with dotted lines, and may have the circuit structure shown in FIG. 3 or FIG. 5. The second pixel drivers PC2r, PC2g, and PC2b may be connected to a side of the cathode connecting lines CL1r, CL1g, and CL1b through the contact hole OPt, and other sides of the cathode connecting lines CL1r, CL1g, and CL1b may be electrically connected to the cathodes Cathode2r, Cathode2g, and Cathode2b of the second-1 light-emitting devices ED2r, ED2g, and ED2b through the contact hole PCo.

Referring to FIG. 13, the contact hole OPt that connects the second pixel drivers PC2r, PC2g, and PC2b and the cathode connecting lines CL1r, CL1g, and CL1b may be arranged in the first direction DR1. The contact hole PCo that connects the cathode connecting lines CL1r, CL1g, and CL1b and the cathodes Cathode2r, Cathode2g, and Cathode2b, in detail, three contact holes PCo that connects the cathode connecting lines CL1r, CL1g, and CL1b and the cathodes Cathode2r, Cathode2g, and Cathode2b through the auxiliary connecting electrode Anode-co of FIG. 14 may be adjacently disposed in the first direction DR1.

The cathodes Cathode2r, Cathode2g, and Cathode2b (hereinafter, main cathodes) of the second-1 light-emitting devices ED2r, ED2g, and ED2b may be separated by the separator SEP, they may extend to the second-2 component area DA2-UPC2, and they may function as the cathode of the second-2 light-emitting devices ED2cr, ED2cg, and ED2cb. The separated cathodes Cathode2r, Cathode2g, and Cathode2b may be distinguished into a portion disposed in the second-1 component area DA2-UPC1, a portion disposed in the second-2 component area DA2-UPC2, and a portion that connects the two portions. In detail, the integrally formed cathodes Cathode2r, Cathode2g, and Cathode2b may include a first portion overlapping the emission layers of the second-1 light-emitting devices ED2r, ED2g, and ED2b in a plan view, a second portion overlapping the emission layer of the second-2 display area DA2-2 in a plan view, and a connector that connects the first portion and the second portion. Here, the connector may have a relatively narrow width compared to the other portions, and the width of the connector may be the width of the direction that is perpendicular to the direction that goes to the second portion from the first portion, for example, the first direction DR1 of FIG. 13. Respective portions of the cathodes Cathode2r, Cathode2g, and Cathode2b may be surrounded by one separator SEP, and at least some of the cathodes Cathode2r, Cathode2g, and Cathode2b may overlap the separator SEP in a plan view.

As a result, currents output by the second pixel drivers PC2r, PC2g, and PC2b may be transmitted to the cathodes Cathode2r, Cathode2g, and Cathode2b of the second-1 light-emitting devices ED2r, ED2g, and ED2b and the second-2 light-emitting devices ED2cr, ED2cg, and ED2cb so that the second-1 light-emitting devices ED2r, ED2g, and ED2b and the second-2 light-emitting devices ED2cr, ED2cg, and ED2cb may emit light.

Referring to FIG. 13, the separator SEP may traverse among the three contact holes PCo on a portion where the three contact holes PCo are adjacent in the first direction DR1 so that the cathodes Cathode2r, Cathode2g, and Cathode2b connected through the three contact holes PCo may be electrically separated. The separator SEP may be bent around the contact holes PCo.

The three contact holes PCo disposed in the first display area DA1 of FIG. 13 may be adjacently disposed in the first direction DR1, the separator SEP may traverse among the three contact holes PCo so that the cathodes Cathode1r, Cathode1g, and Cathode1b connected through the three contact holes PCo may be electrically separated. The separator SEP may be bent around the contact holes PCo.

Referring to FIG. 13, respective light-emitting devices ED2r, ED2g, ED2b, ED2cr, ED2cg, and ED2cb are shown, and the corresponding positions may correspond to the regions in which the emission layers EML2r and EMLc of FIG. 14 included in the respective light-emitting devices ED2r, ED2g, ED2b, ED2cr, ED2cg, and ED2cb are disposed, or they may correspond to the openings OPed and OPedc of FIG. 14 of the pixel defining layer 380 of FIG. 14 or the respective light emitting regions.

The respective cathodes Cathode2r, Cathode2g, and Cathode2b may be electrically separated from each other, and may be separated by the separator SEP. The separator SEP may correspond to a portion marked in gray. The separator SEP may have a planar shape surrounding the respective cathodes Cathode2r, Cathode2g, and Cathode2b, and may separate the adjacent cathodes Cathode2r, Cathode2g, and Cathode2b. As shown in FIG. 14, the respective separators SEP may protrude upward and may be reversely tapered. For example, the cathodes having a reversely tapered side wall and disposed on respective sides of the separator SEP may be electrically separated from each other.

According to the above-noted structure, the component area DA2-UPC may have the light transmitting area TA-UPC, the number of the second pixel drivers PC2r, PC2g, and PC2b may be reduced, the number of the light-emitting devices ED2r, ED2g, ED2b, ED2cr, ED2cg, and ED2cb connected thereto may be increased to thus form the wide light transmitting area TA-UPC, and the other regions may all be formed to be the display area for displaying images.

In an embodiment of FIG. 13, one of the second-2 light-emitting devices ED2cr, ED2cg, and ED2cb may be connected to one of the second pixel drivers PC2r, PC2g, and PC2b, and depending on embodiments, at least two second-2 light-emitting devices ED2cr, ED2cg, and ED2cb may be connected to one of the second pixel drivers PC2r, PC2g, and PC2b.

The second-1 component area DA2-UPC1 and the second-2 component area DA2-UPC2 may be alternately disposed with respect to one column. For example, the second pixel drivers PC2r, PC2g, and PC2b and the second-1 light-emitting devices ED2r, ED2g, and ED2b formed in the second-1 component area DA2-UPC1 may be disposed below the second-2 light-emitting devices ED2cr, ED2cg, and ED2cb, in the second direction DR2, formed in the second-2 component area DA2-UPC2. Therefore, the second-2 component area DA2-UPC2 in which the light transmitting area TA-UPC is disposed may be sparsely disposed.

Referring to FIG. 13, the adjacent second pixel drivers PC2r, PC2g, and PC2b may be disposed in different rows. For example, in case that the second pixel drivers PC2r, PC2g, and PC2b move by one row in the first direction DR1, there may be the second pixel drivers PC2r, PC2g, and PC2b disposed below by one row in a reverse direction of the second direction DR2. In case that the second-1 light-emitting devices ED2r, ED2g, and ED2b and the second-2 light-emitting devices ED2cr, ED2cg, and ED2cb move in the first direction DR1 by one row, there may be a light-emitting device disposed below by one row in the reverse direction of the second direction DR2.

According to the above-noted structure, the border at the end of the component area DA2-UPC may be a bent straight line. As a result, in a like way of the corner DA-C of FIG. 8, the component area DA2-UPC may have a curved border.

The first display area DA1 is shown on the top right of FIG. 13. The structure of the first display area DA1 may be equivalent to what is shown in FIG. 9 so no additional description will be given.

FIG. 14 is a schematic cross-sectional structure of the embodiment of FIG. 13.

FIG. 14 shows a cross-sectional view of a connection of a light-emitting device according to an embodiment of FIG. 13.

As shown in FIG. 7 and FIG. 10, FIG. 14 generally shows the red second-1 light-emitting device ED2r and the second-2 light-emitting device ED2cr, and the second pixel driver at the lower portion may be the red second pixel driver PC2r.

Referring to FIG. 14, the structure disposed at the lower portions of the planarization layers 181 and 182 may be equivalent to what is shown in FIG. 7 and FIG. 10. A cross-sectional structure according to an embodiment of FIG. 14 will now be described with the focus on portions of FIG. 14 that are different from FIG. 7 and FIG. 10.

Referring to FIG. 10, the cathode Cathode2r may be disposed on the pixel defining layer 380 and the separator SEP, and also on the second functional layer FL-2. The respective cathodes Cathode2r may be separated with respect to the separator SEP. A portion (also referred to as a main cathode) overlapping the emission layer EML2r from among the cathode Cathode2r may configure a cathode of the second-1 light-emitting device ED2r, and a portion (also referred to as an additional cathode) overlapping the emission layer EMLc from among the cathode Cathode2r may configure a cathode of the second-2 light-emitting device ED2cr. For example, the cathode of the second-1 light-emitting device ED2r and the cathode of the second-2 light-emitting device ED2cr may be integrally formed into one cathode Cathode2r as shown in FIG. 10.

The second-1 light-emitting device ED2r may include a main cathode that is part of the anode Anode2r, the emission layer EML2r, and the cathode Cathode2r, and may further include a first functional layer FL-1 disposed between the anode Anode2r and the emission layer EML2r and a second functional layer FL-2 disposed between the emission layer EML2r and the main cathode.

The second-2 light-emitting device ED2cr may include an additional cathode that is another part of the anode Anode2cr, the emission layer EMLc, and the cathode Cathode2r, and may further include a first functional layer FL-1 disposed between the anode Anode2cr and the emission layer EMLc and a second functional layer FL-2 disposed between the emission layer EMLc and the additional cathode.

Referring to FIG. 14, a light transmitting area TA-UPC may be disposed between the second-1 light-emitting device ED2r and the second-2 light-emitting device ED2cr. The light transmitting area TA-UPC may not overlap the second pixel drivers PC2r, PC2g, and PC2b, no opaque conductive layer or semiconductor layer may be disposed therein, and a transparent insulating layer may be included. The light transmitting area TA-UPC may overlap the cathode Cathode2r that is a transparent conductive layer, and may overlap the functional layer FL disposed below the cathode Cathode2r. The light transmitting area TA-UPC may not block light by including an opening in the position on which the layer including a light blocking material, for example, the pixel defining layer 380 and/or the light blocking layer (not shown) corresponds to the component area DA2-UPC.

The cathode connecting line CL1r may be connected to the integrally formed cathode Cathode2r and may be electrically connected to the main cathode of the second-1 light-emitting device ED2r and the additional cathode of the second-2 light-emitting device ED2cr.

Depending on embodiments, a spacer may be further formed on the pixel defining layer 380, and the spacer may have a tapered side wall to prevent the cathode from being disconnected.

FIG. 14 does not show the structure disposed on the cathode, but an encapsulation layer may be disposed thereon depending on embodiments. The encapsulation layer may include at least one inorganic film and at least one organic film, and may have a triple-layered structure including a first inorganic encapsulation layer, an organic encapsulation layer, and a second inorganic encapsulation layer. The encapsulation layer may protect the emission layers EML2r and EMLc from moisture or oxygen that may be input from the outside. Depending on embodiments, the encapsulation layer may include a structure in which inorganic layers and organic layers are sequentially further stacked.

Depending on embodiments, a film including a polarizer may be attached to the encapsulation layer to reduce reflection of external light, or a color filter or a color converting layer may be further formed thereon to improve color quality. A light blocking layer may be disposed between the color filter and the color converting layer. Depending on embodiments, a layer on which a material (hereinafter, a reflection adjusting material) for absorbing light with a predetermined or selected wavelength from among external light may be further included. Depending on embodiments, the front side of the light emitting display device may be made flat by covering with the additional planarization layer (or the planarization layer).

According to the above-described structure, the camera disposed on the rear side of the component area DA2-UPC may photograph the front side of the light emitting display device through the light transmitting area TA-UPC, and may display the images by the second-1 light-emitting device ED2r and the second-2 light-emitting device ED2cr disposed in the component area DA2-UPC to thus increase the displaying area.

The structure of the component area DA2-UPC may be different from what is shown in FIG. 13 and FIG. 14. For example, the light transmitting area TA-UPC may be partitioned in the component area DA2-UPC, the lower shielding layer (not shown) made of a metal may be disposed therein, and the second light-emitting device or the pixel driver may be disposed on the lower shielding layer.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the disclosure.

What is claimed is:

1. A light emitting display device, comprising:
a first display area; and
a second display area disposed outside of the first display area, wherein
the second display area includes:
a pixel driver;
a main light-emitting device electrically connected to the pixel driver; and
an additional light-emitting device electrically connected to the main light-emitting device,
the additional light-emitting device overlaps a peripheral driver that generates signals that are provided to the pixel driver,
the main light-emitting device and the additional light-emitting device include a first electrode, an emission layer, and a second electrode,
the pixel driver is electrically connected to the second electrode of the main light-emitting device and the second electrode of the additional light-emitting device, and
the second electrode of the additional light-emitting device and the second electrode of the main light-emitting device are surrounded by a separator in a plan view.

2. The light emitting display device of claim 1, wherein the second electrode of the additional light-emitting device and the second electrode of the main light-emitting device electrically connected to each other are integral to each other.

3. The light emitting display device of claim 2, wherein the second electrode includes:
a first portion overlapping the emission layer of the main light-emitting device in a plan view;
a second portion overlapping the emission layer of the additional light-emitting device in a plan view; and
a connector that connects the first portion and the second portion.

4. The light emitting display device of claim 3, wherein a width of the connector is narrower than a width of the first portion and a width of the second portion.

5. The light emitting display device of claim 1, wherein a first electrode of the main light-emitting device and a first electrode of the additional light-emitting device are electrically connected to a first driving voltage line.

6. The light emitting display device of claim 1, further comprising:
a cathode connecting line that electrically connects the second electrode of the main light-emitting device and the pixel driver.

7. The light emitting display device of claim 6, wherein
the cathode connecting line has a triple-layered structure, and
the second electrode of the main light-emitting device side-contacts the cathode connecting line.

8. The light emitting display device of claim 6, further comprising:
an auxiliary connecting electrode disposed between the second electrode of the main light-emitting device and the cathode connecting line side-contacting each other,
wherein the auxiliary connecting electrode, the first electrode of the main light-emitting device, and the first electrode of the additional light-emitting device are made of a same material.

9. The light emitting display device of claim 8, wherein three contact holes that connects the cathode connecting line and the auxiliary connecting electrode are adjacently disposed in a direction.

10. The light emitting display device of claim 9, wherein
the separator is disposed among the three contact holes in a plan view, and
the separator is bent around the three contact holes.

11. A light emitting display device, comprising:
a first display area; and
a component area surrounded by the first display area and disposed on a front side of a camera disposed on a rear side of the component area, wherein
the component area includes a pixel driver, and a main light-emitting device and an additional light-emitting device that are electrically connected to the pixel driver,
the component area further includes a light transmitting area that transmits light to the camera,
the main light-emitting device and the additional light-emitting device include a first electrode, an emission layer, and a second electrode,
the pixel driver is electrically connected to the second electrode of the main light-emitting device and the second electrode of the additional light-emitting device, and
the second electrode of the additional light-emitting device and the second electrode of the main light-emitting device are surrounded by a separator in a plan view.

12. The light emitting display device of claim 11, wherein the second electrode of the additional light-emitting device and the second electrode of the main light-emitting device electrically connected to each other are integral to each other.

13. The light emitting display device of claim 12, wherein the second electrode includes:
a first portion overlapping the emission layer of the main light-emitting device in a plan view;
a second portion overlapping the emission layer of the additional light-emitting device in a plan view; and
a connector that connects the first portion and the second portion.

14. The light emitting display device of claim 13, wherein a width of the connector is a narrower than a width of the first portion and a width of the second portion.

15. The light emitting display device of claim 11, wherein a first electrode of the main light-emitting device and a first electrode of the additional light-emitting device are electrically connected to a first driving voltage line.

16. The light emitting display device of claim 11, further comprising:
a cathode connecting line that electrically connects the second electrode of the main light-emitting device and the pixel driver.

17. The light emitting display device of claim 16, wherein
the cathode connecting line has a triple-layered structure, and
the second electrode of the main light-emitting device side-contacts the cathode connecting line.

18. The light emitting display device of claim 16, further comprising:
an auxiliary connecting electrode disposed between the second electrode of the main light-emitting device and the cathode connecting line side-contacting each other,
wherein the auxiliary connecting electrode, the first electrode of the main light-emitting device, and the first electrode of the additional light-emitting device are made of a same material.

19. The light emitting display device of claim 18, wherein three contact holes that connect the cathode connecting line and the auxiliary connecting electrode are adjacently disposed in a direction.

20. The light emitting display device of claim 19, wherein
the separator is disposed among the three contact holes in a plan view, and
the separator is bent around the three contact holes.
